(19) United States
(12) Patent Application Publication
(10) Pub. No.: US 2024/0396372 A1
(43) Pub. Date: Nov. 28, 2024

(54) Junction System for Direct-Drive Radiofrequency Power Supply

(71) Applicant: Lam Research Corporation, Fremont, CA (US)

(72) Inventors: Alexander Miller Paterson, San Jose, CA (US); Michael John Martin, Fremont, CA (US); Yuhou Wang, Fremont, CA (US); John Drewery, San Jose, CA (US); Neema Rastgar, San Jose, CA (US)

(21) Appl. No.: 18/689,007

(22) PCT Filed: Sep. 13, 2022
(86) PCT No.: PCT/US2022/043387

§ 371 Date: Mar. 4, 2024

Related U.S. Application Data
(60) Provisional application No. 63/245,785, filed on Sep. 17, 2021.

(51) Int. Cl. H02J 50/10; H01J 37/32; H02J 50/20

(52) U.S. Cl. CPC H02J 50/10; H01J 37/3211; H02J 50/20

(57) ABSTRACT

A junction system for a direct-drive radiofrequency power supply includes a first terminal connected to a radiofrequency signal supply pin that is connected to an output of a direct-drive radiofrequency signal generator. The junction system also includes a second terminal connected to a coil of a plasma processing chamber. The junction system includes a reactive circuit connected between the first terminal and the second terminal. The reactive circuit is configured to transform a shaped-amplified square waveform signal into a shaped-sinusoidal signal in route from the first terminal to the second terminal. The reactive circuit includes a variable capacitor having a capacitance set so that a peak amount of radiofrequency power is transmitted from the direct-drive radiofrequency signal generator through the reactive circuit to the coil.

### BACKGROUND

Plasma processing systems are used to manufacture semiconductor devices, e.g., chips/die, on semiconductor wafers. In the plasma processing system, the semiconductor wafer is exposed to various types of plasma to cause prescribed changes to a condition of the semiconductor wafer, such as through material deposition and/or material removal and/or material implantation and/or material modification, etc. The plasma processing system conventionally includes a radiofrequency (RF) source, an RF transmission cable, an RF impedance matching network, an electrode, and a plasma generation chamber. The RF source is connected to the RF impedance matching network through the RF transmission cable. The RF impedance matching network is connected to the electrode through an electrical conductor. RF power generated by the RF source is transmitted through the RF transmission cable and through the RF impedance matching network to the electrode. RF power transmitted from the electrode causes a process gas to be transformed into a plasma within the plasma generation chamber. It is within this context that embodiments described in the present disclosure arise.

### SUMMARY

In an example embodiment, a junction system is disclosed for an RF power transmission system for a plasma processing chamber. The junction system includes a first terminal configured to connect to a RF signal supply pin that is connected to an output of a direct-drive RF signal generator. The junction system includes a second terminal configured to connect to a coil. The junction system includes a reactive circuit connected between the first terminal and the second terminal. The reactive circuit is configured to transform a shaped-amplified square waveform signal into a shaped-sinusoidal signal in route from the first terminal to the second terminal.

In an example embodiment, an RF power transmission system for a plasma processing chamber is disclosed. The RF power transmission system includes a direct-drive RF signal generator, a coil, and a reactive circuit. The reactive circuit is connected between an output of the direct-drive RF signal generator and the coil. The reactive circuit is connected to receive a shaped-amplified square waveform signal from the output of the direct-drive RF signal generator. The reactive circuit is configured to transform the shaped-amplified square waveform signal into a shaped-sinusoidal signal in route from the direct-drive RF signal generator to the coil.

In an example embodiment, a method is disclosed for delivering RF power from a direct-drive RF power supply to a plasma processing chamber. The method includes transmitting a shaped-amplified square waveform signal from an output of a direct-drive RF signal generator to a reactive circuit. The reactive circuit is operated to transform the shaped-amplified square waveform signal into a shaped-sinusoidal signal. The method also includes transmitting the shaped-sinusoidal signal from an output of the reactive circuit to a coil of the plasma processing chamber. The shaped-sinusoidal signal conveys RF power to the coil. The method also includes adjusting a capacitance setting within the reactive circuit so that a peak amount of RF power is transmitted from the direct-drive RF signal generator through the reactive circuit to the coil.

Other aspects and advantages of the embodiments will become more apparent from the following detailed description and the accompanying drawings.

### BRIEF DESCRIPTION OF THE DRAWINGS

FIG. 1A shows an isometric view of a plasma processing system that includes a direct-drive RF power supply, in accordance with some embodiments.

FIG. 1B shows a front view of the plasma processing system of FIG. 1A, in accordance with some embodiments.

FIG. 1C shows a back view of the plasma processing system of FIG. 1A, in accordance with some embodiments.

FIG. 1D shows a left-side view of the plasma processing system of FIG. 1A, in accordance with some embodiments.

FIG. 1E shows a right-side view of the plasma processing system of FIG. 1A, in accordance with some embodiments.

FIG. 2A shows a top view of the coil assembly, in accordance with some embodiments.

FIG. 2B shows a diagram of a vertical cross-section taken through the plasma processing chamber, in accordance with some embodiments.

FIG. 3 shows an isometric view of the plasma processing system with the direct-drive RF power supply removed to reveal the platform, in accordance with some embodiments.

FIG. 4A shows an isometric view of the plasma processing system with the platform removed to reveal the region within the first RF connection enclosure, the region within the second RF connection enclosure, and the T-shaped interior region of the metrology enclosure, in accordance with some embodiments.

FIG. 4B shows a top view of the plasma processing system with the platform removed, in accordance with some embodiments.

FIG. 5 shows a perspective view of the plasma processing system looking toward the front of the plasma processing system with the removable doors and platform removed, in accordance with some embodiments.

FIG. 6 shows the perspective view of the plasma processing system of FIG. 5 with the first RF jumper structure removed from both the first upper coupling structure and the first lower coupling structure, and with the second RF jumper structure removed from both the second upper coupling structure and the second lower coupling structure, in accordance with some embodiments.

FIG. 7A shows an isometric view of the plasma processing system of FIG. 5 with removal of the first RF connection enclosure, the second RF connection enclosure, the metrology enclosure, the platform, and the direct-drive RF power supply, in accordance with some embodiments.

FIG. 7B shows a front view of the plasma processing system of FIG. 7A, in accordance with some embodiments.

FIG. 7C shows a left-side perspective view of the plasma processing system of FIG. 7A, in accordance with some embodiments.

FIG. 8 shows a bottom view of the plasma processing system with the bottom covers of the first junction enclosure and the second junction enclosure removed to show components of the first reactive circuit and the second reactive circuit, in accordance with some embodiments.

FIG. 9A shows a circuit schematic depicting transmission of RF power from the first direct-drive RF signal generator through the first reactive circuit to the outer coil of the coil assembly, in accordance with some embodiments.

FIG. 9B shows an isometric view of the plasma processing system as shown in FIG. 7A, from a front-left-upper point of view, with the walls of the first junction enclosure removed to reveal the components of the first reactive circuit and with the walls of the second junction enclosure removed to reveal the components of the second reactive circuit, in accordance with some embodiments.

FIG. 9C shows an isometric view of the plasma processing system as shown in FIG. 9B, from a back-left-upper point of view, in accordance with some embodiments.

FIG. 10A shows a circuit schematic depicting transmission of RF power from the second direct-drive RF signal generator through the second reactive circuit to the inner coil of the coil assembly, in accordance with some embodiments.

FIG. 10B shows an isometric view of the plasma processing system as shown in FIG. 7A, from a front-right-upper point of view, with the walls of the first junction enclosure removed to reveal the components of the first reactive circuit and with the walls of the second junction enclosure removed to reveal the components of the second reactive circuit, in accordance with some embodiments.

FIG. 10C shows an isometric view of the plasma processing system as shown in FIG. 10B, from a back-right-lower point of view, in accordance with some embodiments.

FIG. 11 shows a top view of the plasma processing system as shown in FIG. 7A, with the walls of the first junction enclosure removed to reveal the components of the first reactive circuit and with the walls of the second junction enclosure removed to reveal the components of the second reactive circuit, in accordance with some embodiments.

FIG. 12 shows a perspective view (from a front-left-upper point of view) of the connections between the first reactive circuit and the outer coil, and of the connections between the second reactive circuit and the inner coil, in accordance with some embodiments.

FIG. 13 shows a close-up perspective view (from a front-right-upper point of view) of the first reactive circuit, in accordance with some embodiments.

FIG. 14 shows a close-up perspective view (from a front-left-upper point of view) of the second reactive circuit, in accordance with some embodiments.

FIG. 15 shows a schematic of how each of the first direct-drive RF signal generator and the second direct-drive RF signal generator is connected through the corresponding first reactive circuit or second reactive circuit to the coil assembly, in accordance with some embodiments.

FIG. 16 shows a flowchart of a method for delivering RF power from the direct-drive RF power supply to the plasma processing chamber, in accordance with some embodiments.

FIG. 17 shows a schematic diagram of each of the first and second direct-drive RF signal generators, in accordance with some embodiments.

FIG. 18 shows a circuit schematic of the half-bridge FET circuit that implements voltage limiters across the FETs, in accordance with some embodiments.

FIG. 19A shows a plot of a parameter of an example shaped-amplified square waveform generated at the output of the first/second direct-drive RF signal generator as a function of time, in accordance with some embodiments.

FIG. 19B shows a plot of a parameter of an example shaped-sinusoidal waveform generated at the output of the first/second reactive circuit as a function of time, in accordance with some embodiments.

FIG. 20A shows a plot of a parameter of an example shaped-sinusoidal waveform generated at the output of the first/second reactive circuit as a function of time, in accordance with some embodiments.

FIG. 20B shows a plot of a parameter of an example shaped-sinusoidal waveform generated at the output of the first/second reactive circuit as a function of time, in accordance with some embodiments.

FIG. 20C shows a plot of a parameter of an example shaped-sinusoidal waveform generated at the output of the first/second reactive circuit as a function of time, in accordance with some embodiments.

FIG. 20D shows a plot of a parameter of an example shaped-sinusoidal waveform generated at the output of the first/second reactive circuit as a function of time, in accordance with some embodiments.

### DETAILED DESCRIPTION

In the following description, numerous specific details are set forth in order to provide a thorough understanding of the present disclosure. It will be apparent, however, to one skilled in the art that embodiments of the present disclosure may be practiced without some or all of these specific details. In other instances, well known process operations have not been described in detail in order not to unnecessarily obscure the present disclosure.

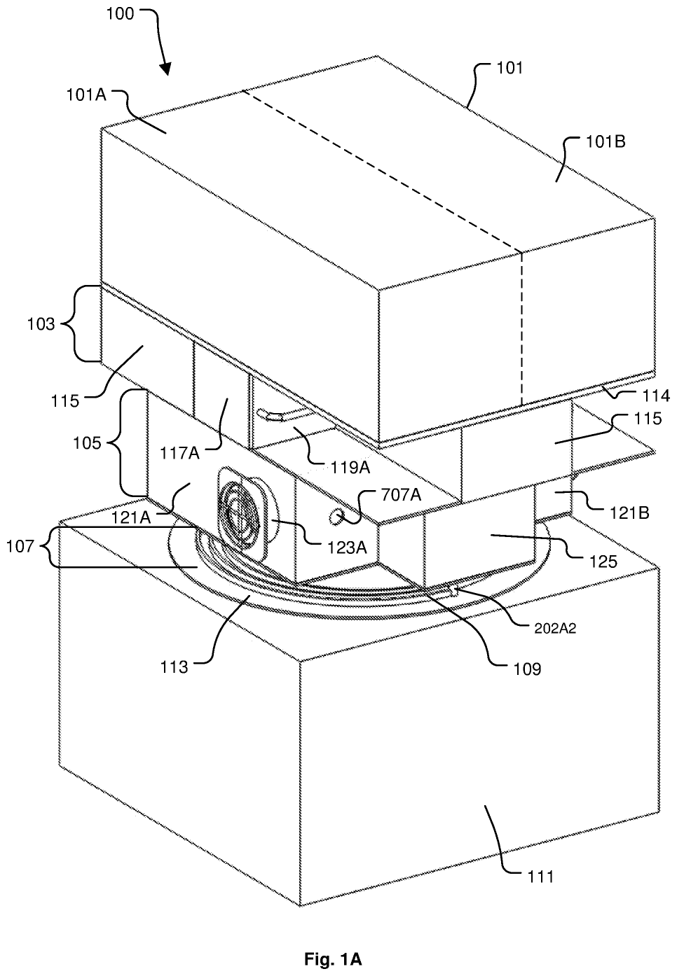

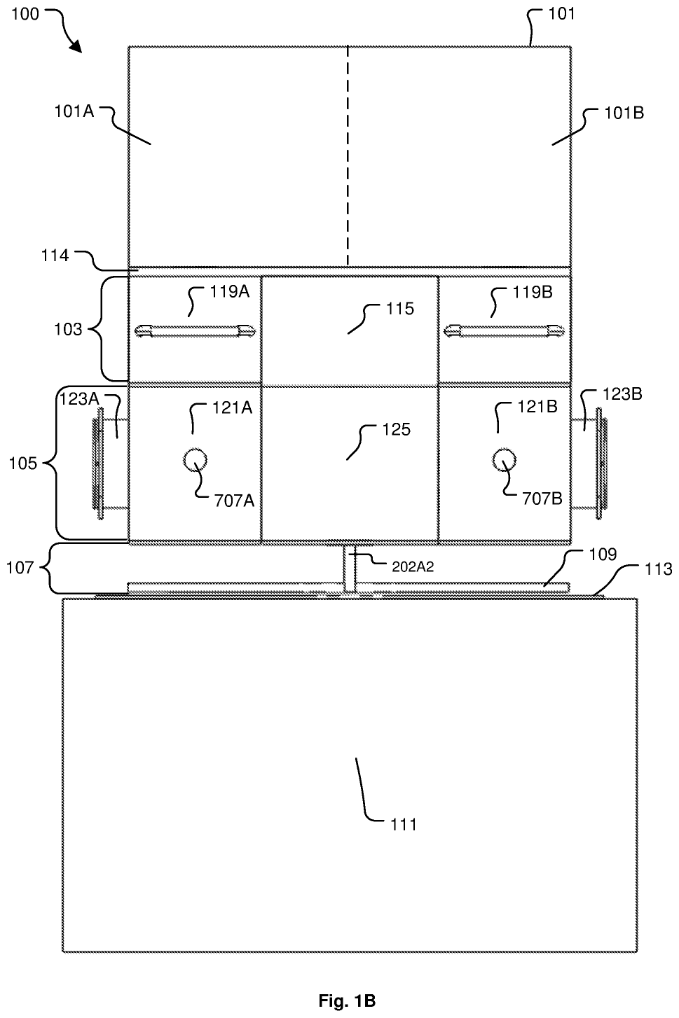

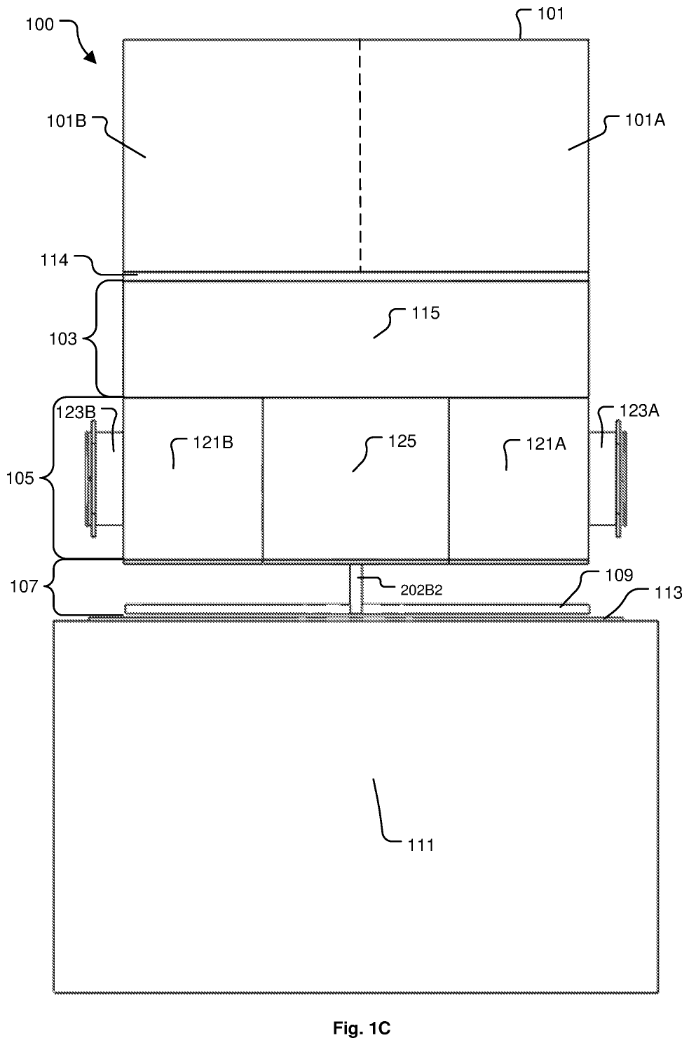

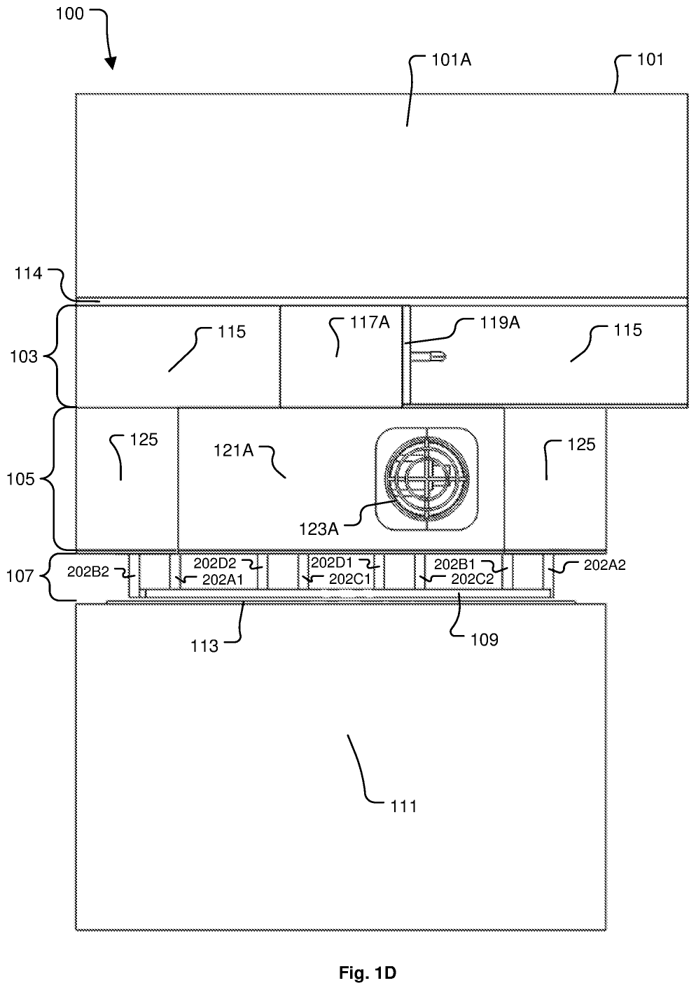

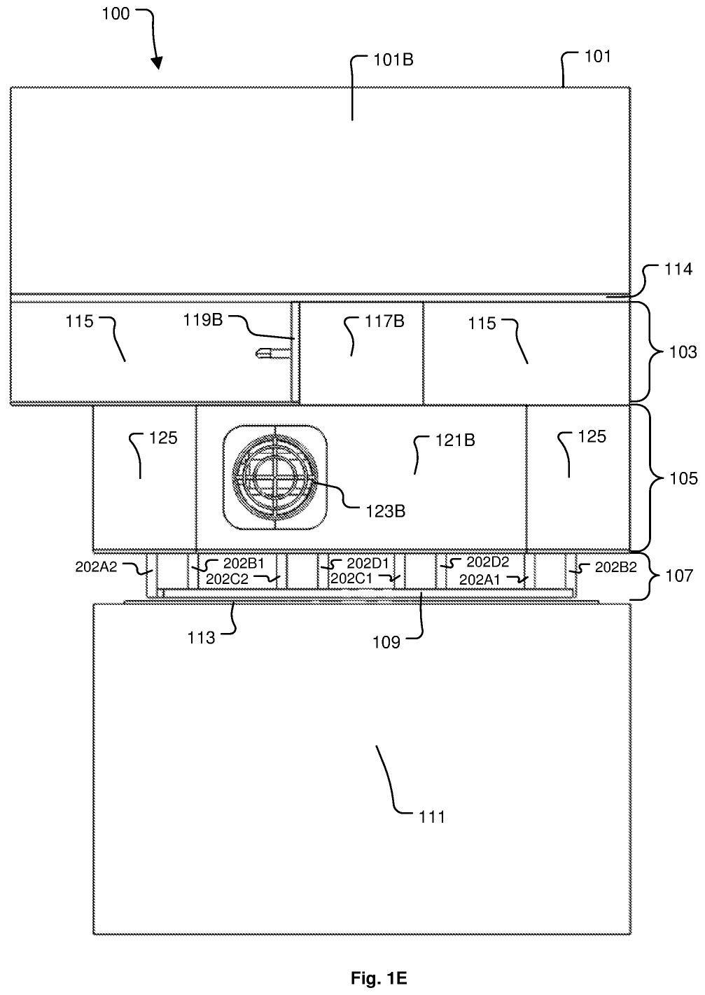

FIG. 1A shows an isometric view of a plasma processing system 100 that includes a direct-drive radiofrequency (RF) power supply 101, in accordance with some embodiments. FIG. 1B shows a front view of the plasma processing system 100, in accordance with some embodiments. FIG. 1C shows a back view of the plasma processing system 100, in accordance with some embodiments. FIG. 1D shows a left-side view of the plasma processing system 100, in accordance with some embodiments. FIG. 1E shows a right-side view of the plasma processing system 100, in accordance with some embodiments.

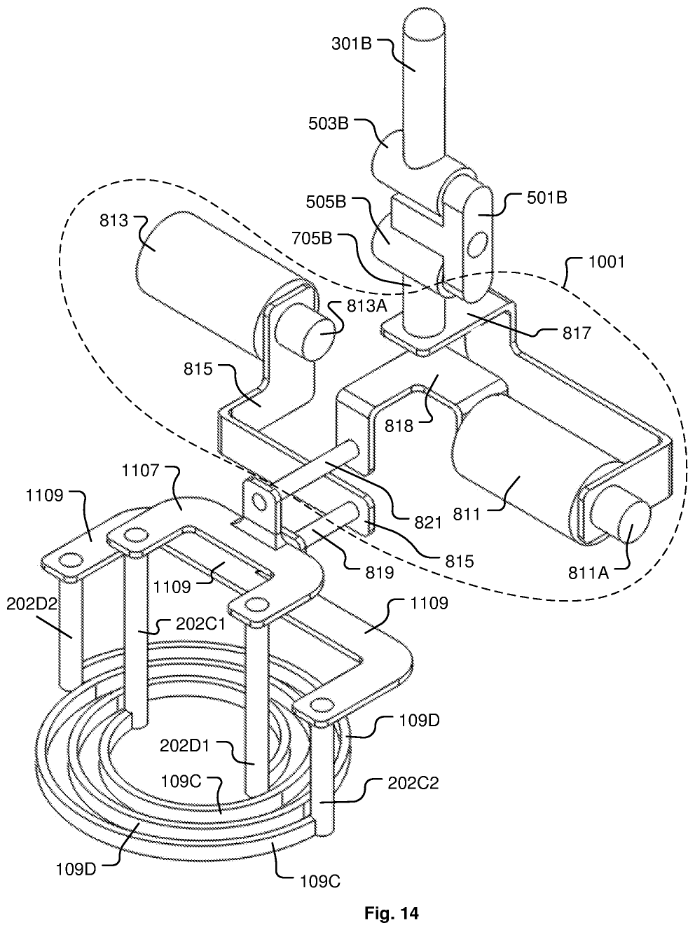

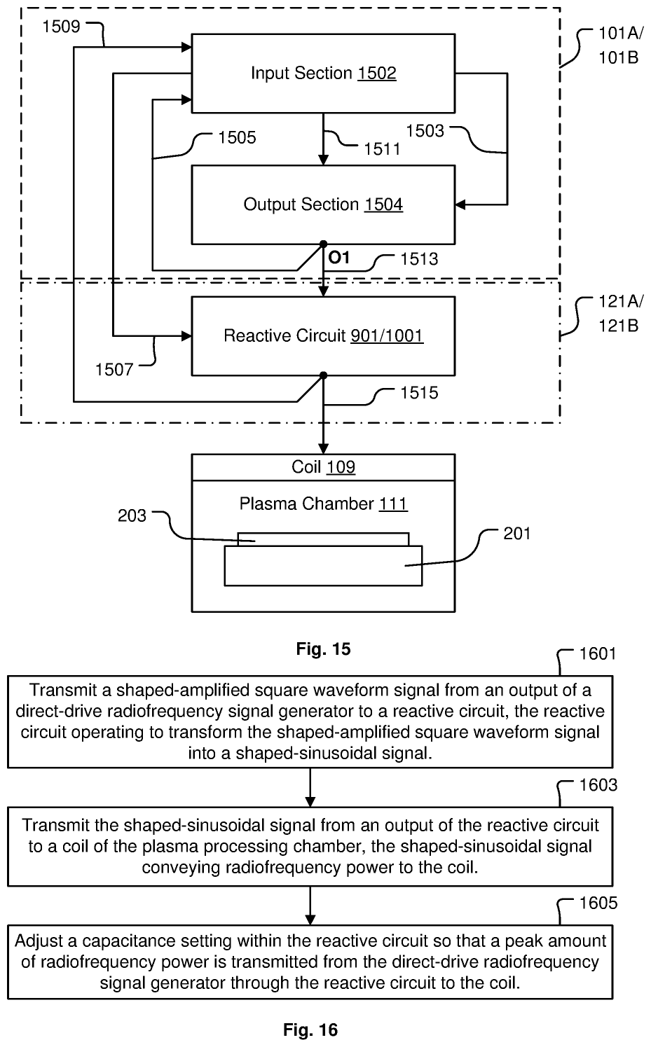

The direct-drive RF power supply 101 is configured to generate and deliver RF power to a plasma processing chamber 111 without having to transmit RF signals through an RF transmission line and an impedance matching network in route to the plasma processing chamber 111. The direct-drive RF power supply 101 is also referred to as a matchless plasma source (MPS). In the example embodiment of FIGS. 1A-1E, the direct-drive RF power supply 101 is connected to deliver RF power to a coil assembly 109 disposed above a window 113 of the plasma processing chamber 111. In various embodiments, the window 113 is formed of a dielectric material, such as quartz, that allows RF power to be transmitted from the coil assembly 109 through the window 113 and into the plasma processing chamber 111. As the RF power is transmitted into and through the plasma processing chamber 111, the RF power transforms a process gas into a plasma within the plasma processing chamber 111 in exposure to a semiconductor wafer that is supported within the plasma processing chamber 111. In various embodiments, the plasma is used to provide controlled modification of a condition of the semiconductor wafer, such as through material deposition and/or material removal and/or material implantation and/or material modification, etc. Also, in some embodiments, a plasma is generated in the plasma processing chamber 111 to provide for cleaning of the plasma processing chamber 111. The direct-drive RF power supply 101 is described in detail below with regard to FIGS. 15 through 20D. For the present discussion, it should be understood that the direct-drive RF power supply 101 is configured to generate RF signals having a prescribed waveform as a function of time, and deliver the generated RF signals to the coil assembly 109.

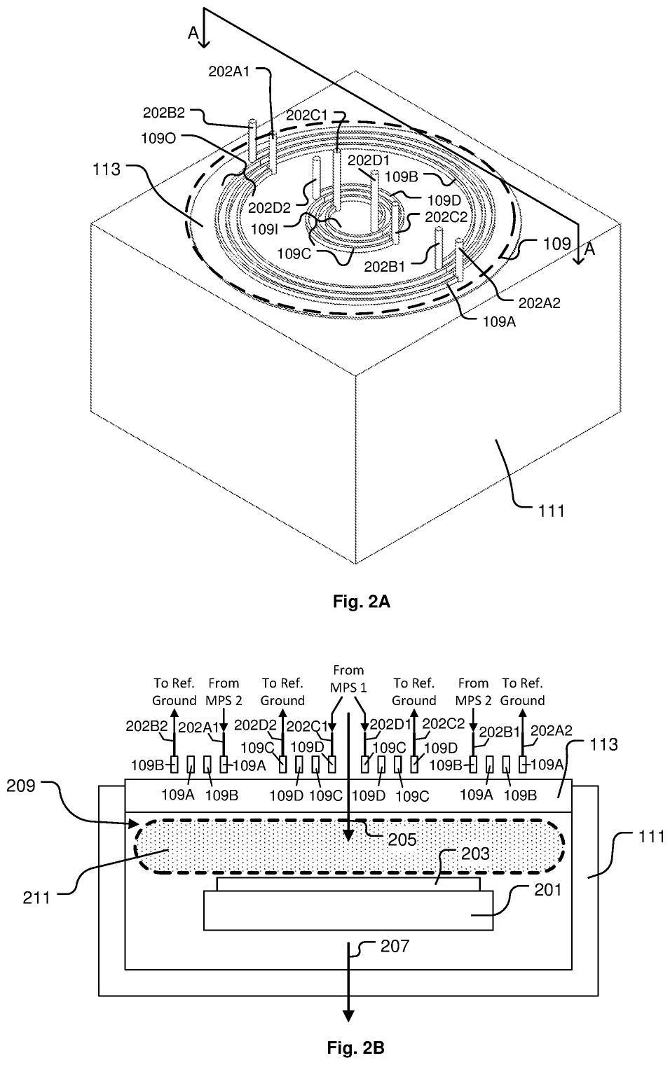

FIG. 2A shows a top view of the coil assembly 109, in accordance with some embodiments. In some embodiments, the coil assembly 109 includes an outer coil 109O that includes a first outer coil winding 109A and a second outer coil winding 109B. In some embodiments, the first outer coil winding 109A and second outer coil winding 109B are interleaved with each other so as to be positioned in an alternating sequence relative to a radial direction extending horizontally outward from the center of the of the coil assembly 109. A first end of the first outer coil winding 109A is connected to receive RF power from the direct-drive RF power supply 101 through a connector 202A1. A second end of the first outer coil winding 109A is connected to a reference ground potential through a connector 202A2. A first end of the second outer coil winding 109B is connected to receive RF power from the direct-drive RF power supply 101 through a connector 202B1. A second end of the second outer coil winding 109B is connected to a reference ground potential through a connector 202B2. In some embodiments, the coil assembly 109 includes an inner coil 109I that includes a first inner coil winding 109C and a second inner coil winding 109D. In some embodiments, the first inner coil winding 109C and second inner coil winding 109D are interleaved with each other so as to be positioned in an alternating sequence relative to a radial direction extending horizontally outward from the center of the of the coil assembly 109. A first end of the first inner coil winding 109C is connected to receive RF power from the direct-drive RF power supply 101 through a connector 202C1. A second end of the first inner coil winding 109C is connected to a reference ground potential through a connector 202C2. A first end of the second inner coil winding 109D is connected to receive RF power from the direct-drive RF power supply 101 through a connector 202D1. A second end of the second inner coil winding 109D is connected to a reference ground potential through a connector 202D2. It should be understood that the coil assembly 109 is shown by way of example. In various embodiments, the coil assembly 109 can include a single coil winding or multiple coil windings. Also, in various embodiments, the multiple windings of the coil assembly 109 can be arranged into multiple, e.g., 2, 3, 4, etc., coil regions, such as the inner coil 109I region and the outer coil 109O region as shown in FIG. 2A. In some embodiments, each coil winding in the coil assembly 109 is connected to receive RF power from the direct-drive RF power supply 101, regardless of the coil assembly 109 configuration.

In some embodiments, the direct-drive RF power supply 101 includes a plurality of direct-drive RF signal generators that independently generate and supply RF signals to different portions of the coil assembly 109. For example, in some embodiments, such as shown in FIGS. 1A-1E, the direct-drive RF power supply 101 includes a first direct-drive RF signal generator 101A and a second direct-drive RF signal generator 101B. The first direct-drive RF signal generator 101A is connected to generate and supply RF signals to the first outer coil winding 109A and the second outer coil winding 109B of the coil assembly 109. The second direct-drive RF signal generator 101B is connected to generate and supply RF signals to the first inner coil windings 109C and the second inner coil winding 109D of the coil assembly 109. It should be understood that in various embodiments the direct-drive RF power supply 101 includes more than two direct-drive RF signal generators for generating and supplying RF signals to more than two coils, respectively, within the coil assembly 109, where each coil in the coil assembly 109 includes one or more coil windings. Also, in some embodiments, the direct-drive RF power supply 101 includes a single direct-drive RF signal generator for generating and supplying RF signals to a single coil within the coil assembly 109, where the single coil includes one or more coil windings.

In some embodiments, such as shown in FIGS. 1A-1E, the direct-drive RF power supply 101 is disposed above the plasma processing chamber 111, with the direct-drive RF power supply 101 being separated from the plasma processing chamber 111 by a metrology level 103, an RF power junction level 105, and a coil assembly level 107. In some embodiments, the metrology level 103 is located vertically between the direct-drive RF power supply 101 and the RF power junction level 105, with the coil assembly level 107 located below the RF power junction level 105. The metrology level 103 includes a metrology enclosure 115. In some embodiments, the metrology enclosure 115 has a T-shaped interior volume when viewed from above the metrology enclosure 115. In various embodiments, metrology equipment, e.g., optical metrology equipment, thermal metrology equipment, electrical metrology equipment, etc., is disposed within the interior volume of the metrology enclosure 115. It should be understood that this provides for positioning metrology equipment in close proximity to the plasma processing chamber 111 and coil assembly 109, which provides for simplification of metrology equipment deployment and connectivity. In some embodiments, a platform 114 is disposed over the metrology enclosure 115. The platform 114 provides a base structure to support the direct-drive RF power supply 101.

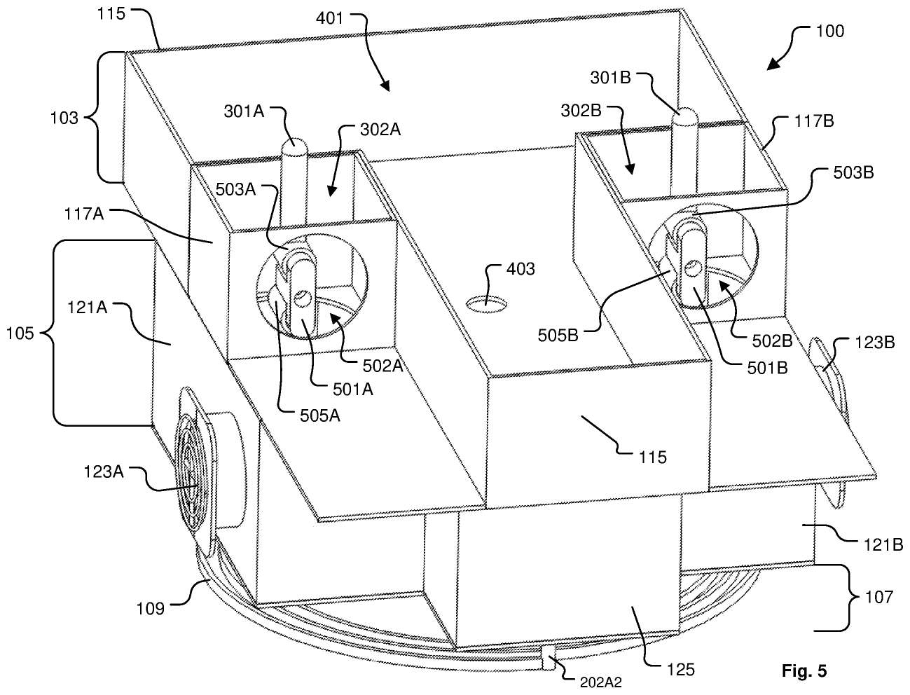

In some embodiments, the metrology level 103 also includes a first RF connection enclosure 117A and a second RF connection enclosure 117B. The first RF connection enclosure 117A is formed to provide a protected region within and through which RF connection structures are disposed to provide for transmission of RF power from the first direct-drive RF signal generator 101A to the outer coil 109O of the coil assembly 109. A removable door 119A is provided to cover an access opening 502A (see FIG. 5) into the region within the first RF connection enclosure 117A. The second RF connection enclosure 117B is formed to provide a protected region within and through which RF connection structures are disposed to provide for transmission of RF power from the second direct-drive RF signal generator 101B to the inner coil 109I of the coil assembly 109. A removable door 119B is provided to cover an access opening 502B (see FIG. 5) into the region within the second RF connection enclosure 117B.

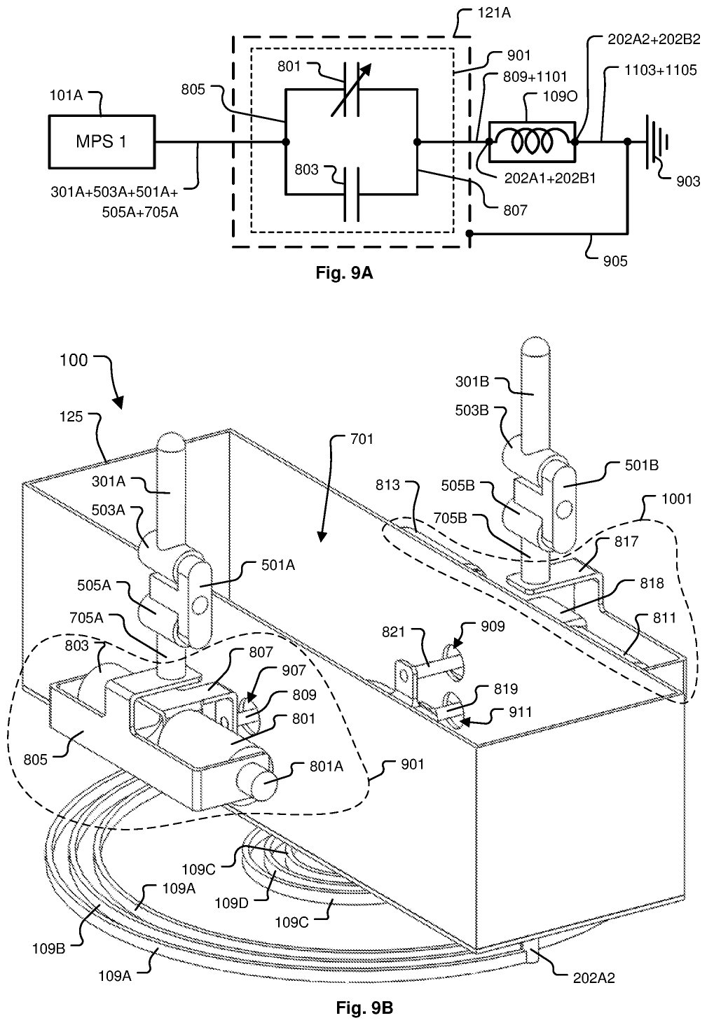

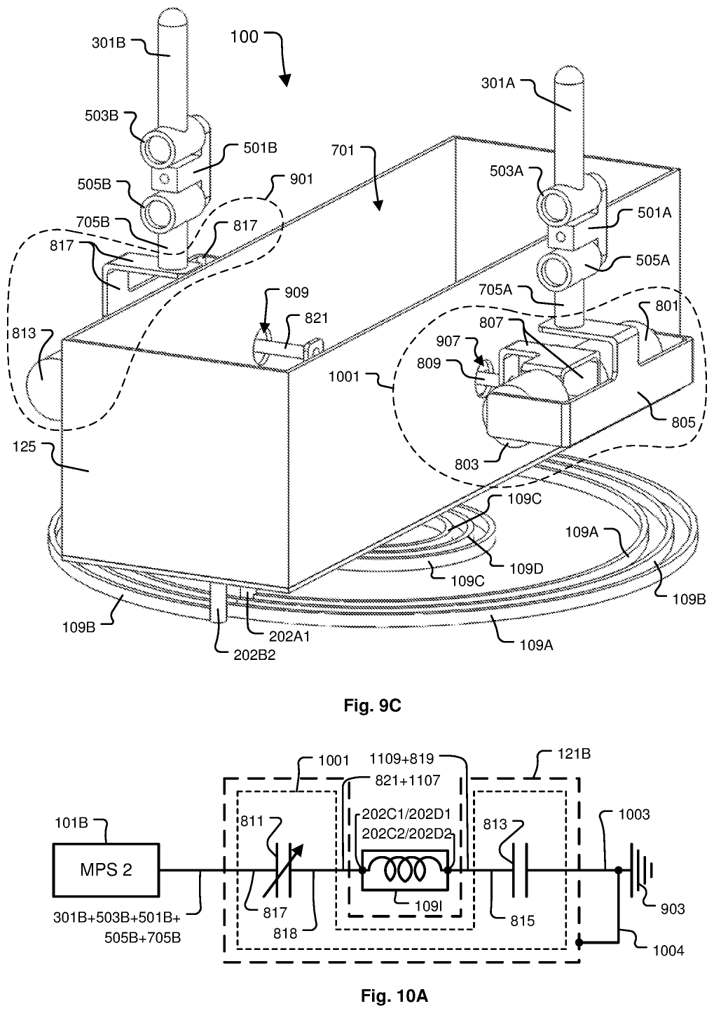

The RF power junction level 105 includes a first junction enclosure 121A, a second junction enclosure 121B, and a coil connection enclosure 125. In some embodiments, the coil connection enclosure 125 is substantially centered on the plasma processing chamber 111 and is correspondingly substantially centered on the coil assembly 109 disposed above the window 113 of the plasma processing chamber 111. The first junction enclosure 121A includes an interior region in which a first reactive circuit 901 (see FIG. 9) is disposed, with the first reactive circuit 901 being connected between the first direct-drive RF signal generator 101A and the outer coil 109O of the coil assembly 109. The first junction enclosure 121A and the first reactive circuit 901 are parts of a first RF junction system.

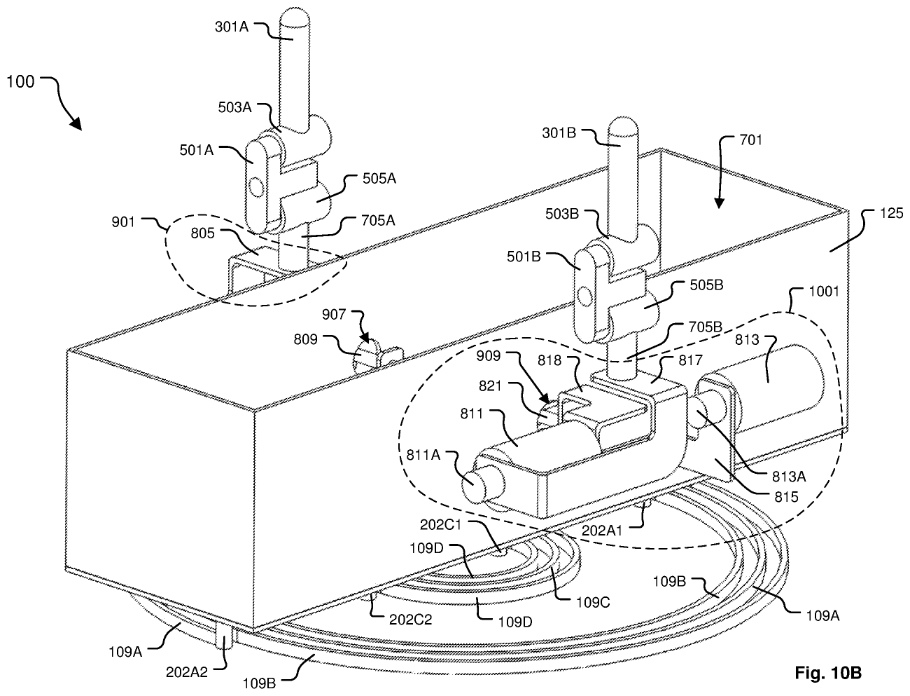

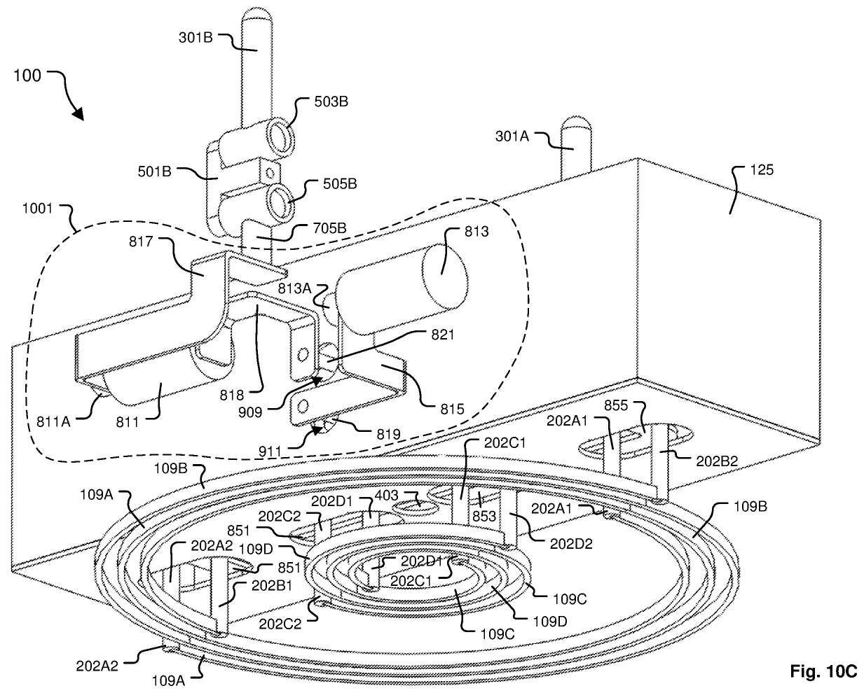

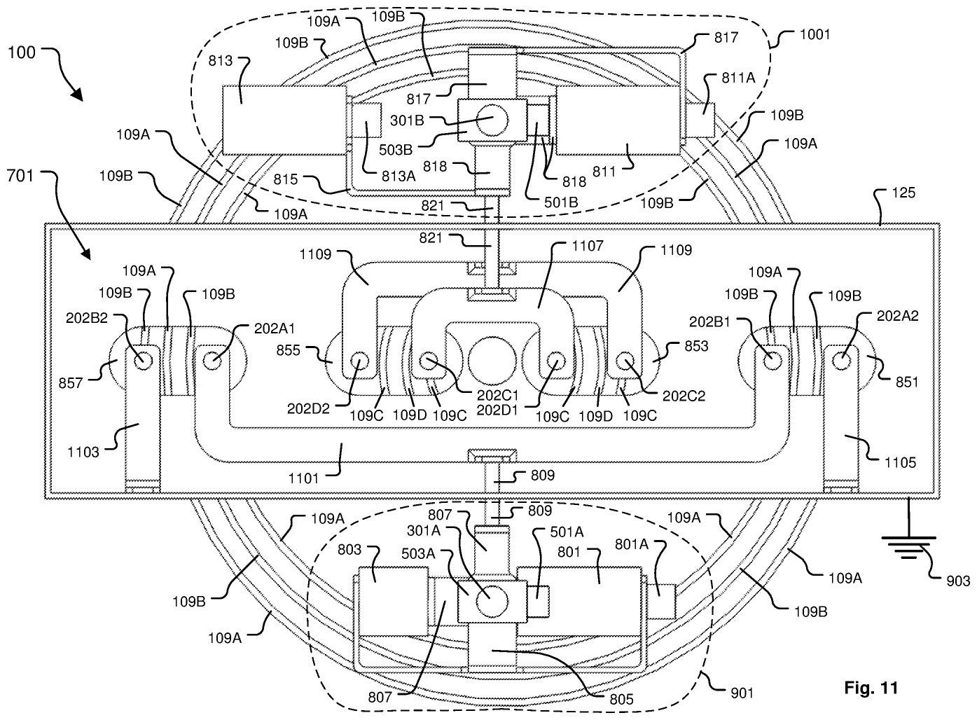

The second junction enclosure 121B includes an interior region in which a second reactive circuit 1001 (see FIG. 10) is disposed, with the second reactive circuit 1001 being connected between the second direct-drive RF signal generator 101B and the inner coil 109I of the coil assembly 109. The second junction enclosure 121B and the second reactive circuit 1001 are parts of a second RF junction system. The coil connection enclosure 125 includes an interior region in which a first conductive structure 1101 (see FIG. 11) is disposed to electrically connect the first reactive circuit 901 to the outer coil 109O of the coil assembly 109, and in which a second conductive structure 1107 (see FIG. 11) is disposed to electrically connect the second reactive circuit 1001 to the inner coil 109I of the coil assembly 109. The coil connection enclosure 125 also houses a third conductive structure 1103 (see FIG. 11) and a fourth conductive structure 1105 (see FIG. 11) to provide for electrical connection of the outer coil 109O of the coil assembly 109 to a reference ground potential, such as to the reference ground potential that exists on the walls of the coil connection enclosure 125. The coil connection enclosure 125 also houses a fifth conductive structure 1109 (see FIG. 11) to provide a ground return electrical connection from the inner coil 109I of the coil assembly 109 to second reactive circuit 1001.

In some embodiments, the first junction enclosure 121A is equipped with a fan 123A to circulate air through the interior region of the first junction enclosure 121A to maintain cooling of components within the first reactive circuit 901. Similarly, in some embodiments, the second junction enclosure 121B is equipped with a fan 123B to circulate air through the interior region of the second junction enclosure 121B to maintain cooling of components within the second reactive circuit 1001. Also, in some embodiments, the first junction enclosure 121A includes an access port 707A through which a device or tool can be disposed to provide for adjustment of one or more of component(s) within the first reactive circuit 901, such as to provide for adjustment of a setting of a variable capacitor within the first reactive circuit 901. Similarly, in some embodiments, the second junction enclosure 121B includes an access port 707B through which a device or tool can be disposed to provide for adjustment of one or more of component(s) within the second reactive circuit 1001, such as to provide for adjustment of a setting of a variable capacitor within the second reactive circuit 1001.

FIG. 2B shows a diagram of a vertical cross-section taken through the plasma processing chamber 111, in accordance with some embodiments. The vertical cross-section diagram of FIG. 2B corresponds to the View A-A as referenced in FIG. 2A. It should be understood that the vertical cross-section diagram of FIG. 2B depicts a simplified representation of the plasma processing chamber 111. In various embodiments, the plasma processing chamber 111 includes other components and features that are not shown in FIG. 2B, in order to avoid unnecessarily obscuring the relevant description of the plasma processing chamber 111. Also, in various embodiments, the components that are depicted in FIG. 2B can be shaped, positioned, and oriented in ways that differ from their particular representation in FIG. 2B, without departing from their intended purpose as discussed herein. The plasma processing chamber 111 includes a substrate support 201, e.g., an electrostatic chuck, on which a substrate 203, e.g., a semiconductor wafer, is supported during plasma processing of the substrate 203. During operation of the plasma processing chamber 111, a process gas is flowed into a processing region 209 within the plasma processing chamber 111, as indicated by arrow 205. Also, during operation of the plasma processing chamber 111, RF power is supplied from the first direct-drive RF signal generator 101A to the outer coil 109O and/or from the second direct-drive RF signal generator 101B to the inner coil 109I. The RF power is transmitted from the inner coil 109I and/or outer coil 109O through the window 113 and through the processing region 209 within the plasma processing chamber 111.

Within the processing region 209, the RF power causes the process gas to transform into a plasma 211 in exposure to the substrate 203 supported on the substrate support 201. Also, during operation of the plasma processing chamber 111, exhaust gases and by-product materials from processing of the substrate 203 are exhausted from the plasma processing chamber 111, as indicated by arrow 207. It should be understood that in various embodiments operation of the plasma processing chamber 111 can include many other additional operations, such as generating a bias voltage at the substrate 203 level to attract or repel electrically charged constituents of the plasma 211 toward or away from the substrate 203, and/or controlling a temperature of the substrate 203, and/or applying additional RF power to one or more electrode(s) disposed within the substrate support 201 to generate additional plasma 211, among other additional operations. Also, in various embodiments, the plasma processing chamber 111 is operated in accordance with a prescribed recipe that specifies a temporal schedule for controlling one or more of: supply of process gas(es) to the processing region 209, pressure and temperature within the processing region 209, supply of RF power to the inner coil 109I and/or outer coil 109O, supply of bias voltage at the substrate 203 level, supply of RF power to electrode(s) within the substrate holder 201, among essentially any other process parameter associated with plasma processing of the substrate 203.

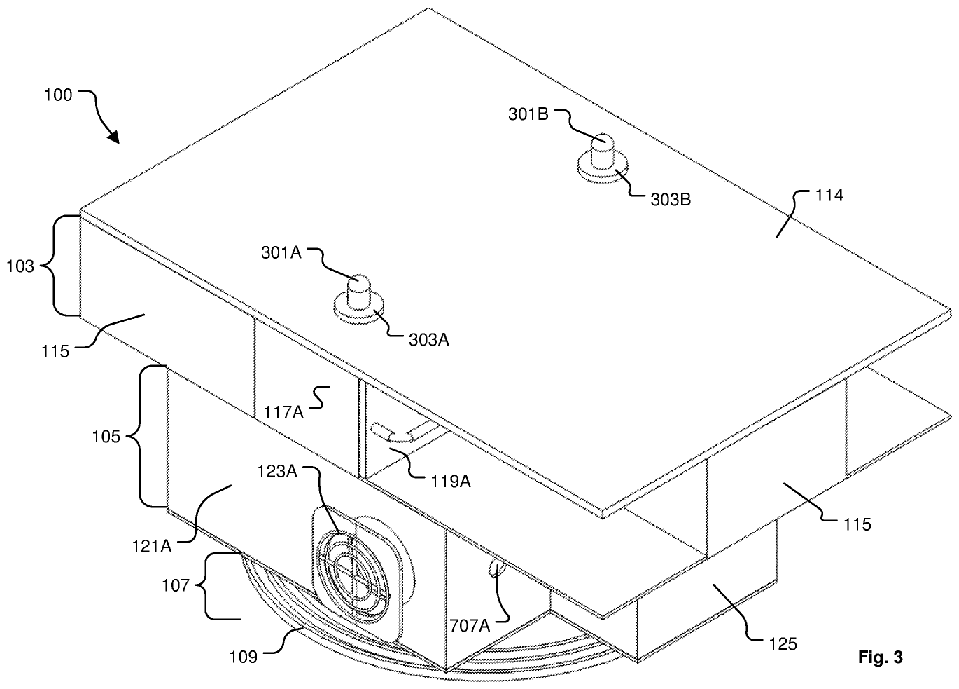

FIG. 3 shows an isometric view of the plasma processing system 100 with the direct-drive RF power supply 101 removed to reveal the platform 114, in accordance with some embodiments. A first upper RF connection structure 301A extends from the region within the first RF connection enclosure 117A through the platform 114 to connect with an RF supply output of the first direct-drive RF signal generator 101A. The first upper RF connection structure 301A is formed of electrically conductive material over which RF power is readily transmitted. In some embodiments, an RF insulator structure 303A is disposed between the first upper RF connection structure 301A and the platform 114 to prevent RF power from coupling to the platform 114. In some embodiments, instead of the RF insulator structure 303A, an open space is maintained between the first upper RF connection structure 301A and the platform 114 to prevent RF power from coupling to the platform 114. In some embodiments, a combination of open space and a variation of the RF insulator structure 303A is provided between the first upper RF connection structure 301A and the platform 114 to prevent RF power from coupling to the platform 114. A second upper RF connection structure 301B extends from the region within the second RF connection enclosure 117B through the platform 114 to connect with an RF supply output of the second direct-drive RF signal generator 101B. The second upper RF connection structure 301B is formed of electrically conductive material over which RF power is readily transmitted. In some embodiments, an RF insulator structure 303B is disposed between the second upper RF connection structure 301B and the platform 114 to prevent RF power from coupling to the platform 114. In some embodiments, instead of the RF insulator structure 303B, an open space is maintained between the second upper RF connection structure 301B and the platform 114 to prevent RF power from coupling to the platform 114. In some embodiments, a combination of open space and a variation of the RF insulator structure 303B is provided between the second upper RF connection structure 301B and the platform 114 to prevent RF power from coupling to the platform 114.

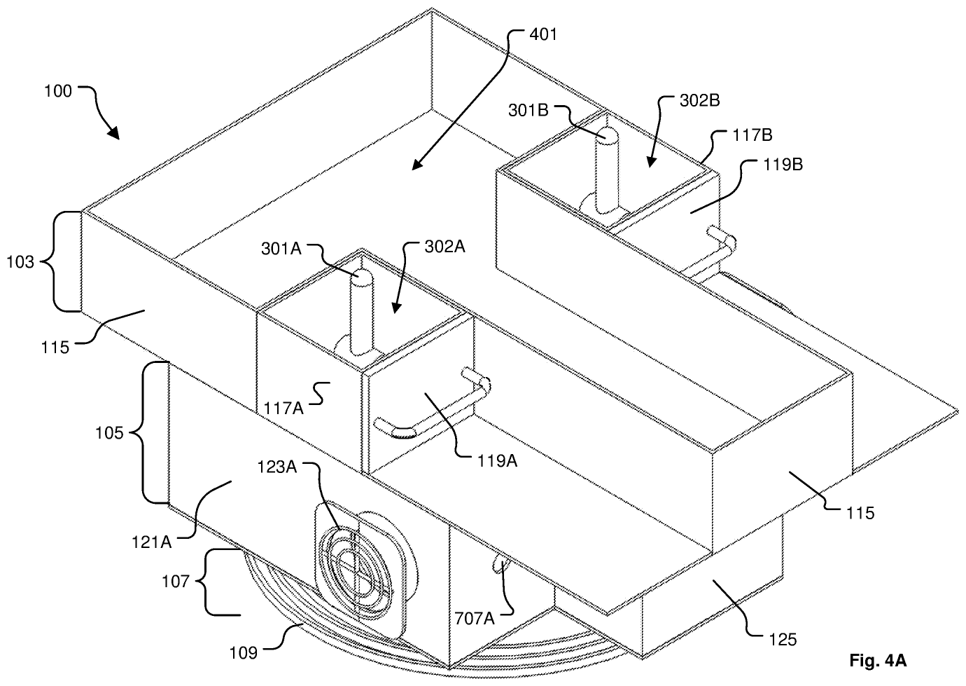

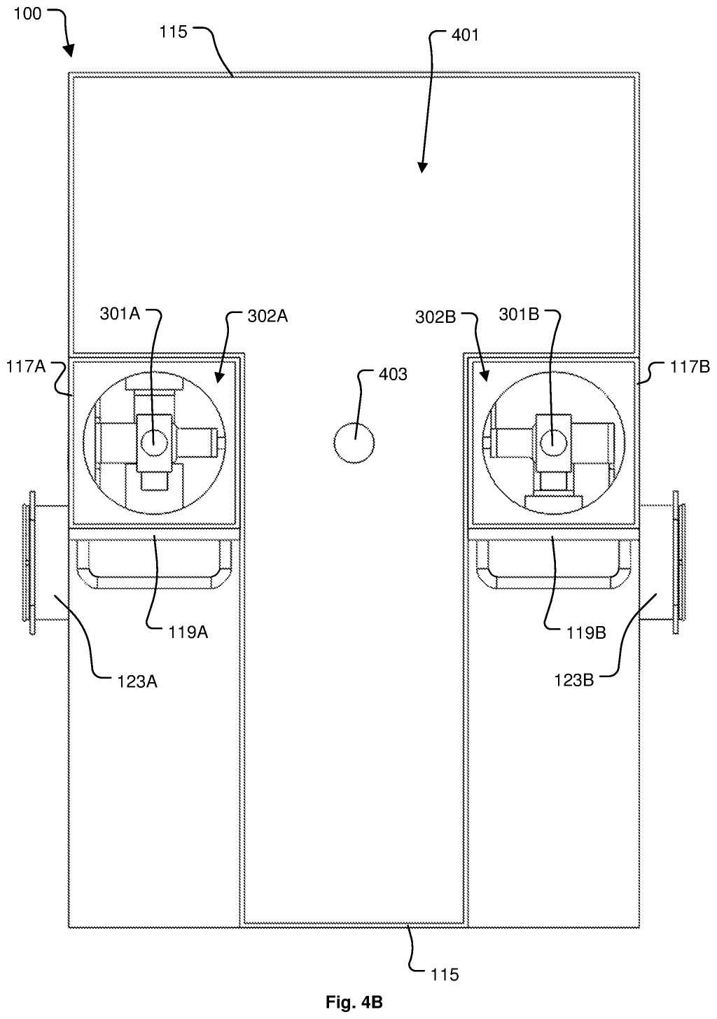

FIG. 4A shows an isometric view of the plasma processing system 100 with the platform 114 removed to reveal the region 302A within the first RF connection enclosure 117A, the region 302B within the second RF connection enclosure 117B, and the T-shaped interior region 401 of the metrology enclosure 115, in accordance with some embodiments. As previously mentioned, in various embodiments, metrology equipment such as optical metrology equipment, and/or thermal metrology equipment, and/or electrical metrology equipment, among other types of metrology equipment is/are disposed within the T-shaped interior region 401 of the metrology enclosure 115. FIG. 4B shows a top view of the plasma processing system 100 with the platform 114 removed, in accordance with some embodiments. In some embodiments, a viewport 403 is formed through the bottom of the metrology enclosure 115 to provide an unobscured line-of-sight view through the window 113 into the processing region 209 within the plasma processing chamber 111. In some embodiments, the viewport 403 is used by an optical metrology device disposed within the interior region 401 of the metrology enclosure 115 to obtain a direct line-of-sight of the plasma 211 generated in the processing region 209 within the plasma processing chamber 111.

FIG. 5 shows a perspective view of the plasma processing system 100 looking toward the front of the plasma processing system 100 with the removable doors 119A and 119B and platform 114 removed, in accordance with some embodiments. Specifically, the removable door 119A is removed to reveal the access opening 502A into the region 302A within the first RF connection enclosure 117A. Similarly, the removable door 119B is removed to reveal the access opening 502B into the region 302B within the second RF connection enclosure 117B. In some embodiments, the first upper RF connection structure 301A extends downward to connect with a first upper coupling structure 503A. The first upper coupling structure 503A is formed of electrically conductive material over which RF power is readily transmitted. A first lower coupling structure 505A is positioned below a spaced apart from the first upper coupling structure 503A within the interior region 302A of the first RF connection enclosure 117A. The first lower coupling structure 505A is formed of electrically conductive material over which RF power is readily transmitted. In some embodiments, each of the first upper coupling structure 503A and the first lower coupling structure 505A is formed to have as substantially annular cylindrical shape with a corresponding cylindrical axis positioned in a substantially horizontal orientation pointed toward the access opening 502A of the first RF connection enclosure 117A.

A first RF jumper structure 501A is configured to insert into both the first upper coupling structure 503A and the first lower coupling structure 505A to establish an electrical connection between the first upper coupling structure 503A and the first lower coupling structure 505A. The first RF jumper structure 501A is formed of electrically conductive material over which RF power is readily transmitted. In some embodiments, the first RF jumper structure 501A is configured to physically contact both the first upper coupling structure 503A and the first lower coupling structure 505A when the first RF jumper structure 501A is inserted into the openings of both the first upper coupling structure 503A and the first lower coupling structure 505A. In this manner, with the first RF jumper structure 501A simultaneously inserted into the openings of both the first upper coupling structure 503A and the first lower coupling structure 505A, RF power supplied to the first upper RF connection structure 301A from the first direct-drive RF signal generator 101A is transmitted over the first upper coupling structure 503A to first RF jumper structure 501A, and over the first RF jumper structure 501A to the first lower coupling structure 505A.

A second RF jumper structure 501B is configured to insert into both a second upper coupling structure 503B and a second lower coupling structure 505B to establish an electrical connection between the second upper coupling structure 503B and the second lower coupling structure 505B. The second RF jumper structure 501B is formed of electrically conductive material over which RF power is readily transmitted. In some embodiments, the second RF jumper structure 501B is configured to physically contact both the second upper coupling structure 503B and the second lower coupling structure 505B when the second RF jumper structure 501B is inserted into the openings of both the second upper coupling structure 503B and the second lower coupling structure 505B. In this manner, with the second RF jumper structure 501B simultaneously inserted into the openings of both the second upper coupling structure 503B and the second lower coupling structure 505B, RF power supplied to the second upper RF connection structure 301B from the second direct-drive RF signal generator 101B is transmitted over the second upper coupling structure 503B to second RF jumper structure 501B, and over the second RF jumper structure 501B to the second lower coupling structure 505B.

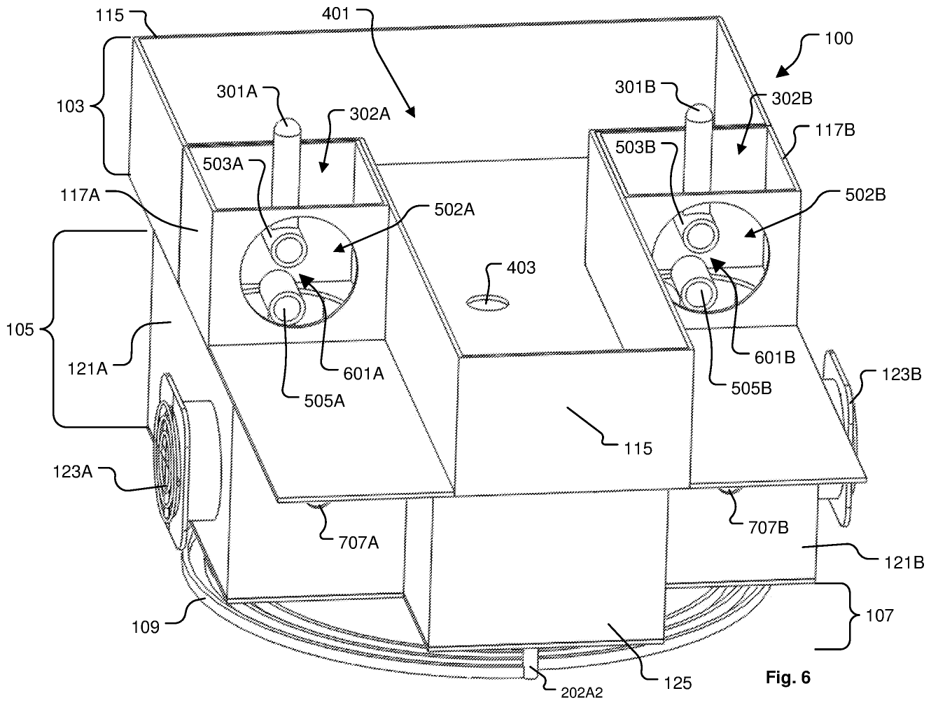

FIG. 6 shows the perspective view of the plasma processing system 100 of FIG. 5 with the first RF jumper structure 501A removed from both the first upper coupling structure 503A and the first lower coupling structure 505A, and with the second RF jumper structure 501B removed from both the second upper coupling structure 503B and the second lower coupling structure 505B, in accordance with some embodiments. In some embodiments, the first RF jumper structure 501A is accessible through the opening 502A of the first RF connection enclosure 117A for slidable removal from and insertion into both the first upper coupling structure 503A and the first lower coupling structure 505A. Similarly, in some embodiments, the second RF jumper structure 501B is accessible through the opening 502B of the first RF connection enclosure 117B for slidable removal from and insertion into both the second upper coupling structure 503B and the second lower coupling structure 505B. Removal of the first RF jumper structure 501A, as indicated by arrow 601A, serves to disconnect the first upper coupling structure 503A from the first lower coupling structure 505A so that RF power does not travel from the first upper coupling structure 503A to the first lower coupling structure 505A. Similarly, removal of the second RF jumper structure 501B, as indicated by arrow 601B, serves to disconnect the second upper coupling structure 503B from the second lower coupling structure 505B so that RF power does not travel from the second upper coupling structure 503B to the second lower coupling structure 505B.

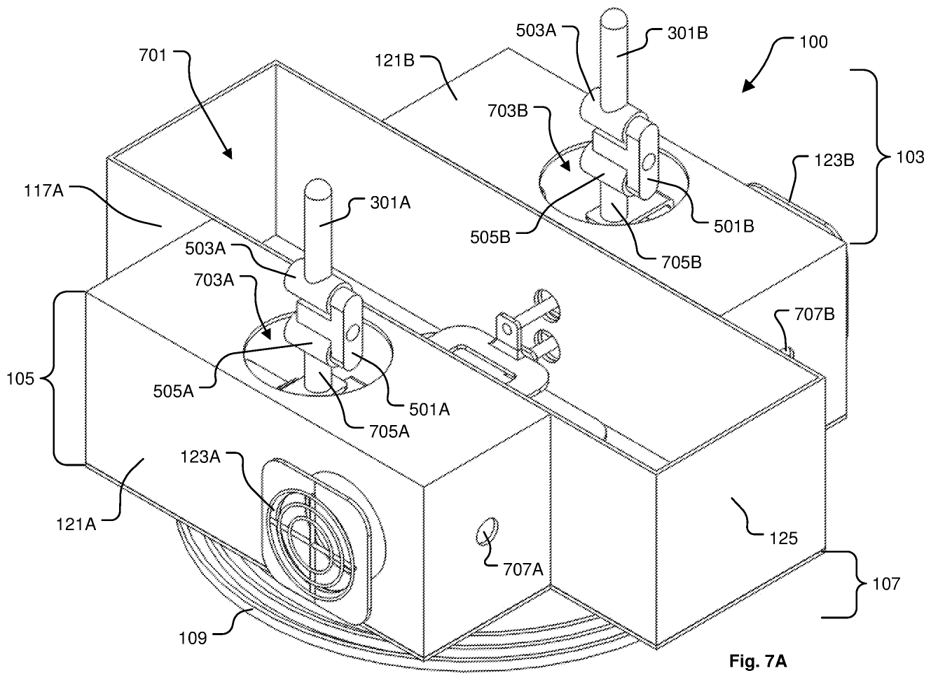

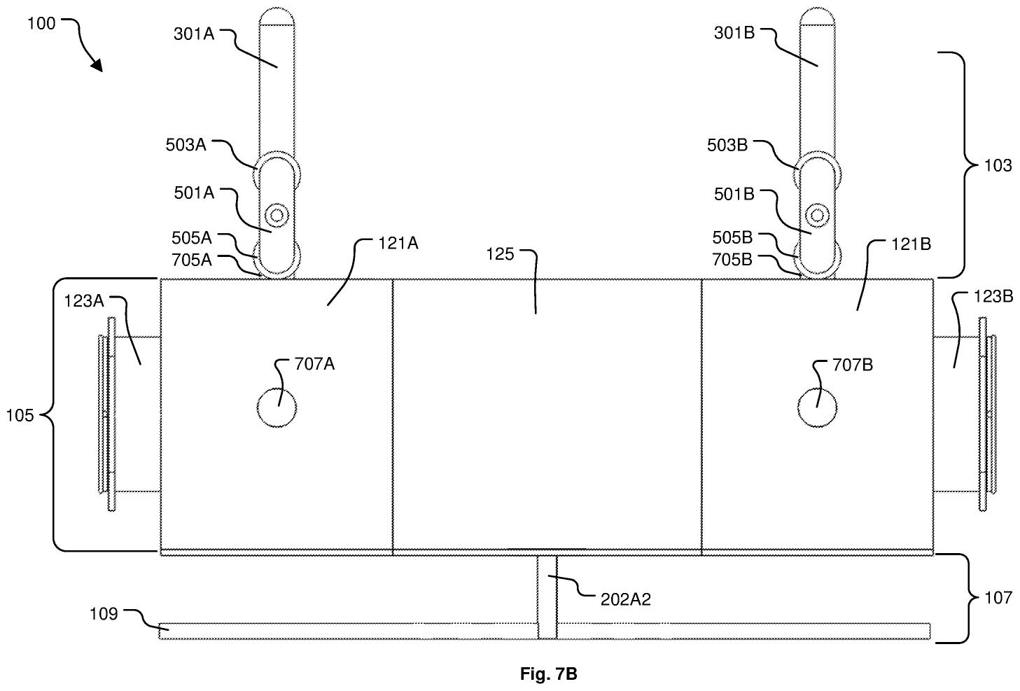

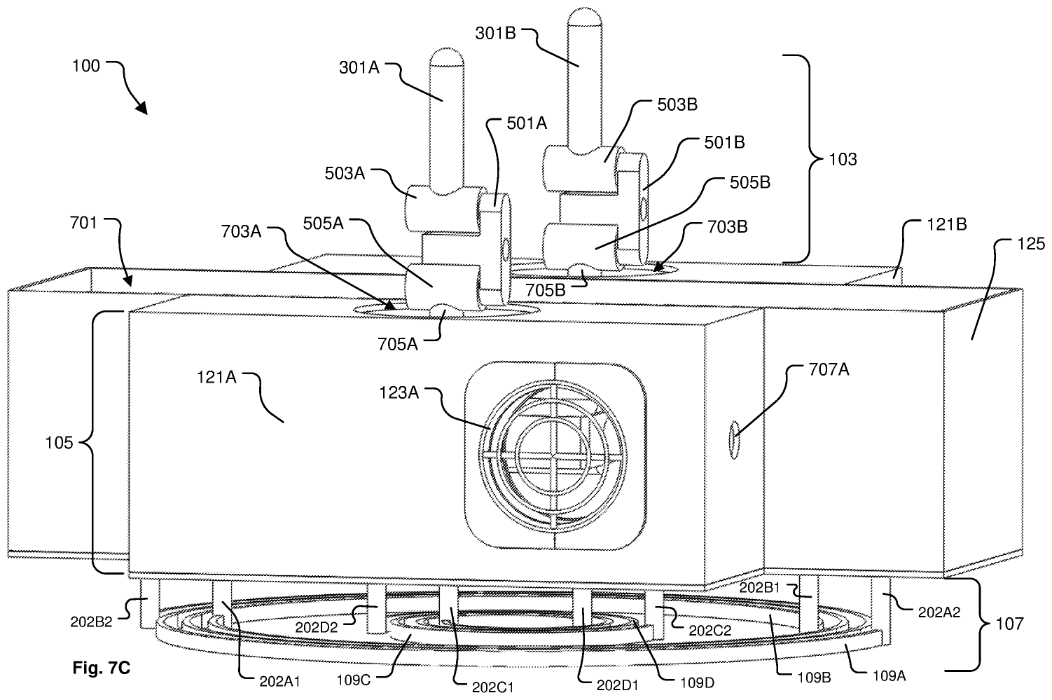

FIG. 7A shows an isometric view of the plasma processing system 100 of FIG. 5 with removal of the first RF connection enclosure 117A, the second RF connection enclosure 117B, the metrology enclosure 115, the platform 114, and the direct-drive RF power supply 101, in accordance with some embodiments. FIG. 7B shows a front view of the plasma processing system 100 of FIG. 7A, in accordance with some embodiments. FIG. 7C shows a left-side perspective view of the plasma processing system 100 of FIG. 7A, in accordance with some embodiments. FIGS. 7A-7C show the first RF jumper structure 501A inserted into both the first upper coupling structure 503A and the first lower coupling structure 505A. FIGS. 7A-7C also show the second RF jumper structure 501B inserted into both the second upper coupling structure 503B and the second lower coupling structure 505B. FIGS. 7A and 7C also show a open region 701 inside the coil connection enclosure 125. The first lower coupling structure 505A is connected to a first lower RF connection structure 705A that extends from the region 302A inside the first RF connection enclosure 117A to a region 703A inside the first junction enclosure 121A. The first lower RF connection structure 705A is formed of electrically conductive material over which RF power is readily transmitted. In some embodiments, the first lower RF connection structure 705A extends through an opening in the top of the first junction enclosure 121A that is sized large enough to ensure that RF power is not coupled from the first lower RF connection structure 705A to the first junction enclosure 121A walls. The second lower coupling structure 505B is connected to a second lower RF connection structure 705B that extends from the region 302B inside the second RF connection enclosure 117B to a region 703B inside the second junction enclosure 121B. The second lower RF connection structure 705B is formed of electrically conductive material over which RF power is readily transmitted. In some embodiments, the second lower RF connection structure 705B extends through an opening in the top of the second junction enclosure 121B that is sized large enough to ensure that RF power is not coupled from the second lower RF connection structure 705B to the second junction enclosure 121B walls.

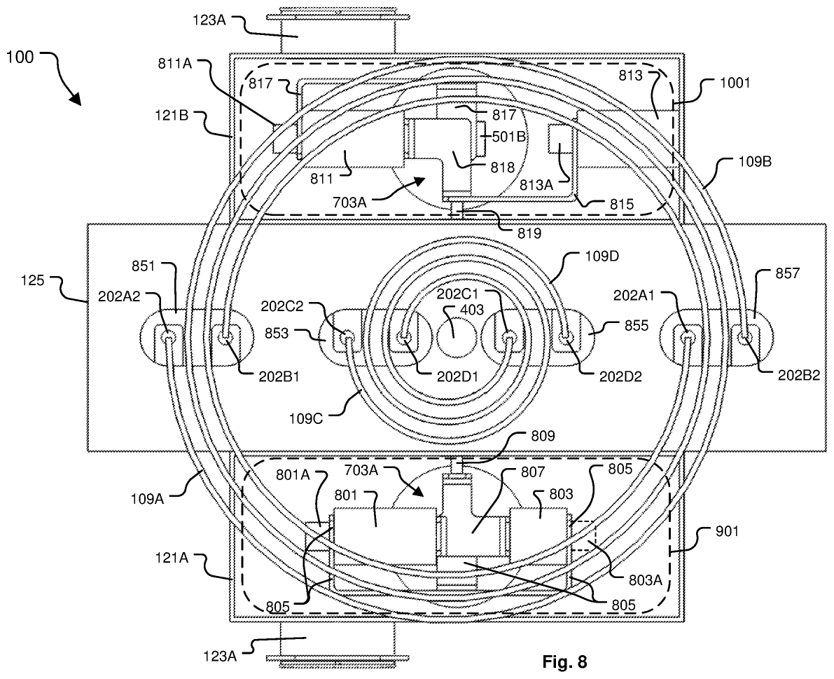

FIG. 8 shows a bottom view of the plasma processing system 100 with the bottom covers of the first junction enclosure 121A and the second junction enclosure 121B removed to show components of the first reactive circuit 901 and the second reactive circuit 1001, in accordance with some embodiments. The first junction enclosure 121A includes the first reactive circuit 901, which is described below with regard to FIGS. 9A-9C. The first reactive circuit 901 includes a first capacitor 801 and a second capacitor 803. In some embodiments, the first capacitor 801 is a variable capacitor and the second capacitor 803 is a fixed capacitor. In some embodiments, the first capacitor 801 is a variable capacitor that includes a capacitance setting control 801A that is physically accessible through the access port 707A on the front wall of the first junction enclosure 121A. In some embodiments, the capacitance setting control 801A is adjustable by using a tool, e.g., screwdriver, inserted through the access port 707A on the front wall of the first junction enclosure 121A. In some embodiments, the capacitance setting control 801A includes a stepper motor that is connected to control the capacitance setting of the first capacitor 801, where the stepper motor is controlled by signals that are conveyed either electrically or wirelessly to the stepper motor, thereby enabling automated and/or remote adjustment of the capacitance setting control 801A.

An input terminal of the first capacitor 801 is electrically connected through a connection structure 805 to the first lower RF connection structure 705A. An input terminal of the second capacitor 803 is also electrically connected through the connection structure 805 to the first lower RF connection structure 705A. The connection structure 805 is formed of electrically conductive material over which RF power is readily transmitted. In some embodiments, the connection structure 805 is formed as an electrically conductive articulated strap structure. An output terminal of the first capacitor 801 is electrically connected through a connection structure 807 to a connector 809 that extends through an opening 907 (see FIG. 9B) from the region 703A inside the first junction enclosure 121A to the region 701 inside the coil connection enclosure 125. The connector 809 is formed of electrically conductive material over which RF power is readily transmitted. An output terminal of the second capacitor 803 is also electrically connected through the connection structure 807 to the connector 809. The connection structure 807 is formed of electrically conductive material over which RF power is readily transmitted. In some embodiments, the connection structure 807 is formed as an electrically conductive articulated strap structure. The connector 809 is electrically connected to the first conductive structure 1101 disposed within the region 701 inside the coil connection enclosure 125 (see FIG. 11), such that the first reactive circuit 901 is electrically connected to the outer coil 109O of the coil assembly 109 through the connector 809 and the first conductive structure 1101. In this manner, RF power is transmitted from the first reactive circuit 901 to the outer coil 109O by way of the connection structure 807, the connector 809, and the first conductive structure 1101.

The second junction enclosure 121B includes the second reactive circuit 1001, which is described below with regard to FIGS. 10A-10C. The second reactive circuit 1001 includes a first capacitor 811 and a second capacitor 813. In some embodiments, the first capacitor 811 is a variable capacitor and the second capacitor 813 is a fixed capacitor. In some embodiments, the first capacitor 811 is a variable capacitor and the second capacitor 813 is also a variable capacitor. In some embodiments, the first capacitor 811 is a variable capacitor that includes a capacitance setting control 811A that is physically accessible through the access port 707B on the front wall of the second junction enclosure 121B. In some embodiments, the capacitance setting control 811A is adjustable by using a tool, e.g., screwdriver, inserted through the access port 707B on the front wall of the second junction enclosure 121B. In some embodiments, the capacitance setting control 811A includes a stepper motor that is connected to control the capacitance setting of the first capacitor 811, where the stepper motor is controlled by signals that are conveyed either electrically or wirelessly to the stepper motor, thereby enabling automated and/or remote adjustment of the capacitance setting control 811A. In some embodiments, the second capacitor 813 is a variable capacitor that includes a capacitance setting control 813A that is physically accessible through the access port 707B on the front wall of the second junction enclosure 121B. In some embodiments, the capacitance setting control 813A is adjustable by using a tool, e.g., screwdriver, inserted through the access port 707B on the front wall of the second junction enclosure 121B or through another access port formed through some wall of the second junction enclosure 121B. In some embodiments, the capacitance setting control 813A includes a stepper motor that is connected to control the capacitance setting of the second capacitor 813, where the stepper motor is controlled by signals that are conveyed either electrically or wirelessly to the stepper motor, thereby enabling automated and/or remote adjustment of the capacitance setting control 813A.

An input terminal of the first capacitor 811 is electrically connected through a connection structure 817 to the second lower RF connection structure 705B (see FIG. 9B). The connection structure 817 is formed of electrically conductive material over which RF power is readily transmitted. In some embodiments, the connection structure 817 is formed as an electrically conductive articulated strap structure. An output terminal of the first capacitor 811 is electrically connected through a connection structure 818 to a connector 821 (see FIG. 9B) that extends through an opening 909 (see FIG. 9B) from the region 703B inside the second junction enclosure 121B to the region 701 inside the coil connection enclosure 125. The connector 821 is formed of electrically conductive material over which RF power is readily transmitted. The connector 821 is electrically connected to the second conductive structure 1107 disposed within the region 701 inside the coil connection enclosure 125 (see FIG. 11), such that the second reactive circuit 1001 is electrically connected to the inner coil 109I of the coil assembly 109 through the connector 821 and the second conductive structure 1107. In this manner, RF power is transmitted from the second reactive circuit 1001 to the inner coil 109I by way of the connection structure 817, the connector 821, and the second conductive structure 1107.

An input terminal of the second capacitor 813 is electrically connected to a connection structure 815. The connection structure 815 is electrically connected to a connector 819. The connector 819 extends through an opening 911 from the region 703B inside the second junction enclosure 121B to the region 701 inside the coil connection enclosure 125. The connector 819 is electrically connected to the fifth conductive structure 1109 disposed within the region 701 inside the coil connection enclosure 125 (see FIG. 11), such that a ground return electrical connection extends from the inner coil 109I of the coil assembly 109 through second reactive circuit 1001. Each of the connection structure 815 and the connector 819 is formed of electrically conductive material over which RF power is readily transmitted. In some embodiments, the connection structure 815 is formed as an electrically conductive articulated strap structure. An output terminal of the second capacitor 813 is also electrically connected to a reference ground potential 903. In some embodiments, the output terminal of the second capacitor 813 is electrically connected to the wall of the second junction enclosure 121B, where the wall of the second junction enclosure 121B is electrically connected to the reference ground potential 903. In some embodiments, the output terminal of the second capacitor 813 is physically attached to the wall of the second junction enclosure 121B.

FIG. 9A shows a circuit schematic depicting transmission of RF power from the first direct-drive RF signal generator 101A through the first reactive circuit 901 to the outer coil 109O of the coil assembly 109, in accordance with some embodiments. The circuit schematic of FIG. 9A shows the input terminals of the first capacitor 801 and a second capacitor 803 electrically connected to the output of the first direct-drive RF signal generator 101A through a combination of the first upper RF connection structure 301A, the first upper coupling structure 503A, the first RF jumper structure 501A, the first lower coupling structure 505A, the first lower RF connection structure 705A, and the connection structure 805. The circuit schematic of FIG. 9A also shows the output terminals of the first capacitor 801 and a second capacitor 803 electrically connected to the RF supply ends of the outer coil 109O through a combination of the connection structure 807, the connector 809, the first conductive structure 1101, and the connectors 202A1 and 202B1. The circuit schematic of FIG. 9A also shows the ground return ends of the outer coil 109O electrically connected to the reference ground potential 903 through a combination of the connector 202A2, the third conductive structure 1103 (see FIG. 11), the connector 202B2, and the fourth conductive structure 1105 (see FIG. 11). The circuit schematic of FIG. 9A also shows the walls of the first junction enclosure 121A electrically connected to the reference ground potential 903 through an electrical connection 905. The combination of the first capacitor 801 and a second capacitor 803 effectively cancels the series inductance of the outer coil 109O to provide a series resonance in order to make the load seen by the first direct-drive RF signal generator 101A real.

FIG. 9B shows an isometric view of the plasma processing system 100 as shown in FIG. 7A, from a front-left-upper point of view, with the walls of the first junction enclosure 121A removed to reveal the components of the first reactive circuit 901 and with the walls of the second junction enclosure 121B removed to reveal the components of the second reactive circuit 1001, in accordance with some embodiments. FIG. 9C shows an isometric view of the plasma processing system 100 as shown in FIG. 9B, from a back-left-upper point of view, in accordance with some embodiments.

FIG. 10A shows a circuit schematic depicting transmission of RF power from the second direct-drive RF signal generator 101B through the second reactive circuit 1001 to the inner coil 109I of the coil assembly 109, in accordance with some embodiments. The circuit schematic of FIG. 10A shows the input terminal of the first capacitor 811 electrically connected to the output of the second direct-drive RF signal generator 101B through a combination of the second upper RF connection structure 301B, the second upper coupling structure 503B, the second RF jumper structure 501B, the second lower coupling structure 505B, the first lower RF connection structure 705B, and the connection structure 817. The circuit schematic of FIG. 10A also shows the output terminal of the first capacitor 811 electrically connected to the RF supply ends of the inner coil 109I through a combination of the connection structure 818, the connector 821, the second conductive structure 1107, and the connectors 202C1 and 202C1. The circuit schematic of FIG. 10A also shows the ground return ends of the inner coil 109I electrically connected to the input terminal of the second capacitor 813 through a combination of the connectors 202C2 and 202D2, the fifth conductive structure 1109 (see FIG. 11), the connector 819, and the connection structure 815. The circuit schematic of FIG. 10A also shows the output terminal of the second capacitor 813 electrically connected to the reference ground potential 903 through an electrical connection 1003. The circuit schematic of FIG. 10A also shows the walls of the second junction enclosure 121B electrically connected to the reference ground potential 903 through an electrical connection 1004.

The capacitor 811 effectively cancels the series inductance of the inner coil 109I to provide a series resonance in order to make the load seen by the second direct-drive RF signal generator 101B real. Also, the capacitor 813 provides for balancing of the inner coil 109I so that the voltages at the two ends of first inner coil winding 109C are out of phase with respect to the reference ground potential 903 (meaning that these end voltages are at about one-half of the voltage with respect to the reference ground potential) and so that the voltages at the two ends of second inner coil winding 109D are also out of phase with respect to the reference ground potential 903 (meaning that these end voltages are at about one-half of the voltage with respect to the reference ground potential). This balancing of the inner coil 109I by the capacitor 813 helps prevent damage to the window 113 caused by plasma 211 sputtering because the voltage difference between the terminals of the inner coil 109I and the plasma 211 is reduced.

FIG. 10B shows an isometric view of the plasma processing system 100 as shown in FIG. 7A, from a front-right-upper point of view, with the walls of the first junction enclosure 121A removed to reveal the components of the first reactive circuit 901 and with the walls of the second junction enclosure 121B removed to reveal the components of the second reactive circuit 1001, in accordance with some embodiments. FIG. 10C shows an isometric view of the plasma processing system 100 as shown in FIG. 10B, from a back-right-lower point of view, in accordance with some embodiments.

FIG. 11 shows a top view of the plasma processing system 100 as shown in FIG. 7A, with the walls of the first junction enclosure 121A removed to reveal the components of the first reactive circuit 901 and with the walls of the second junction enclosure 121B removed to reveal the components of the second reactive circuit 1001, in accordance with some embodiments. The first conductive structure 1101 disposed within the region 701 inside the coil connection enclosure 125 is configured to electrically connect the connector 809 to each of the connectors 202A1 and 202B1. In this manner RF power is supplied from the first reactive circuit 901 over the first conductive structure 1101 to the RF supply ends of the first outer coil winding 109A and second outer coil winding 109B of the outer coil 109O. The second conductive structure 1107 disposed within the region 701 inside the coil connection enclosure 125 is configured to electrically connect the connector 821 to each of the connectors 202C1 and 202D1. In this manner RF power is supplied from the second reactive circuit 1001 over the second conductive structure 1107 to the RF supply ends of the first inner coil winding 109C and second inner coil winding 109D of the inner coil 109I. The third conductive structure 1103 disposed within the region 701 inside the coil connection enclosure 125 is configured to electrically connect the ground return end of the first outer coil winding 109A to the reference ground potential 903 by way of the coil connection enclosure 125. Similarly, the fourth conductive structure 1105 disposed within the region 701 inside the coil connection enclosure 125 is configured to electrically connect the ground return end of the second outer coil winding 109B to the reference ground potential 903 by way of the coil connection enclosure 125. The fifth conductive structure 1109 disposed within the region 701 inside the coil connection enclosure 125 is configured to electrically connect the connector 819 to each of the connectors 202C2 and 202D2. In this manner, an RF ground return path is provided from the ground return ends of the first inner coil winding 109C and the second inner coil winding 109D over the fifth conductive structure 1109 to the input terminal of the second capacitor 813 within the second reactive circuit 1001.

FIG. 11 also shows an opening 851 formed in the bottom the coil connection enclosure 125 through which the connectors 202A2 and 202B1 extend to connected with the outer coil 109O. An opening 853 is also formed in the bottom the coil connection enclosure 125 through which the connectors 202C2 and 202D1 extend to connected with the inner coil 109I. An opening 855 is also formed in the bottom the coil connection enclosure 125 through which the connectors 202C1 and 202D2 extend to connected with the inner coil 109I. An opening 857 is also formed in the bottom the coil connection enclosure 125 through which the connectors 202A1 and 202B2 extend to connected with the outer coil 109O.

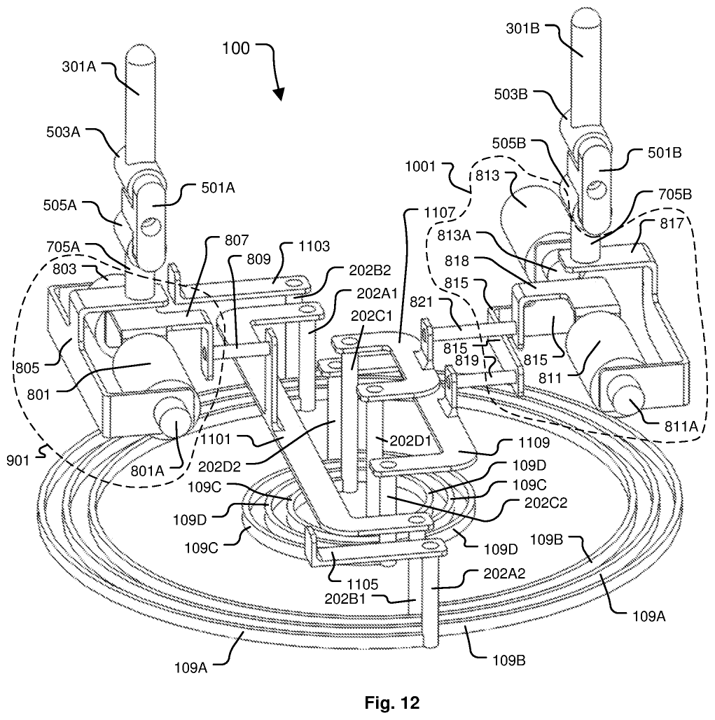

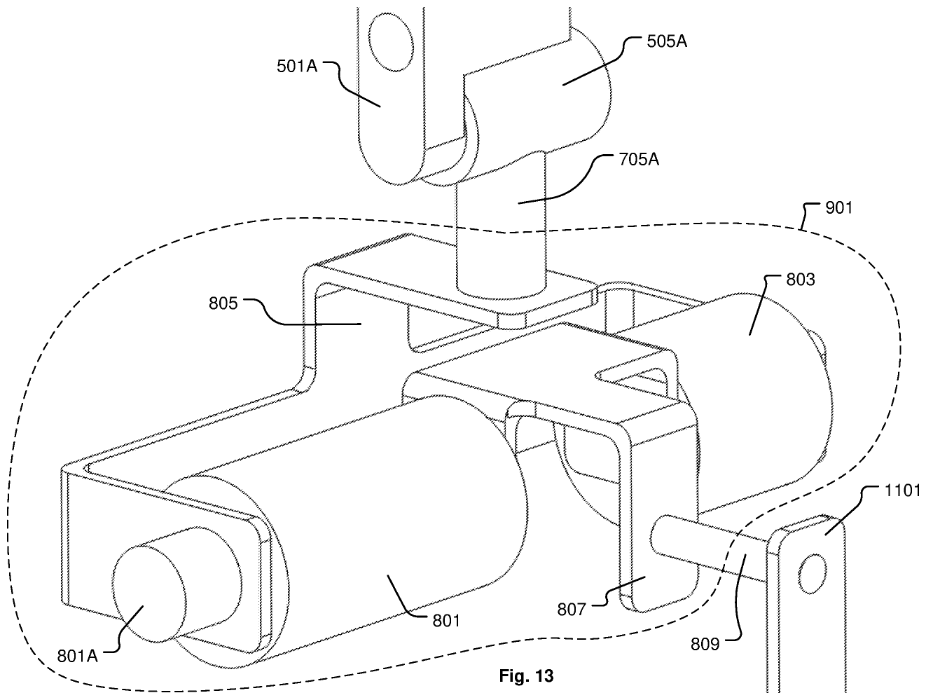

FIG. 12 shows a perspective view (from a front-left-upper point of view) of the connections between the first reactive circuit 901 and the outer coil 109O, and of the connections between the second reactive circuit 1001 and the inner coil 109I, in accordance with some embodiments. The various components shown in FIG. 12 are the same as previously described with regard to FIGS. 1A through 1I. FIG. 13 shows a close-up perspective view (from a front-right-upper point of view) of the first reactive circuit 901, in accordance with some embodiments. The various components shown in FIG. 13 are the same as previously described with regard to FIGS. 1A through 1I. FIG. 14 shows a close-up perspective view (from a front-left-upper point of view) of the second reactive circuit 1001, in accordance with some embodiments. The various components shown in FIG. 14 are the same as previously described with regard to FIGS. 1A through 1I.

FIG. 15 shows a schematic of how each of the first direct-drive RF signal generator 101A and the second direct-drive RF signal generator 101B is connected through the corresponding first reactive circuit 901 or second reactive circuit 1001 to the coil assembly 109, in accordance with some embodiments. Each of the first direct-drive RF signal generator 101A and the second direct-drive RF signal generator 101B includes an input section 1502 and an output section 1504. The input section 1502 is electrically connected to the output section 1504, as indicated by the arrow 1511. For the first direct-drive RF signal generator 101A, the output section 1504 is electrically connected to the first reactive circuit 901, as indicated by the arrow 1513. For the first direct-drive RF signal generator 101A, the arrow 1513 represents the combination of the first upper RF connection structure 301A, the first upper coupling structure 503A, the first RF jumper structure 501A, the first lower coupling structure 505A, and the first lower RF connection structure 705A. For the second direct-drive RF signal generator 101B, the output section 1504 is electrically connected to the second reactive circuit 1001, as indicated by the arrow 1513. For the second direct-drive RF signal generator 101B, the arrow 1513 represents the combination of the second upper RF connection structure 301B, the second upper coupling structure 503B, the second RF jumper structure 501B, the second lower coupling structure 505B, and the second lower RF connection structure 705B. The first reactive circuit 901 is electrically connected to the outer coil 109O, as indicated by the arrow 1515. For the first reactive circuit 901, the arrow 1515 represents the combination of the connector 809, the first conductive structure 1101, and the connectors 202A1 and 202B1. The second reactive circuit 1001 is electrically connected to the inner coil 109I, as indicated by the arrow 1515. For the second reactive circuit 1001, the arrow 1515 represents the combination of the connector 821, the second conductive structure 1107, and the connectors 202C1 and 202C1.

The input section 1502 includes an electrical signal generator and a portion of a gate driver. The output section 1504 includes a remaining portion of the gate driver and a half-bridge transistor circuit. In some embodiments, the input section 1502 includes a controller board on which the electrical signal generator and the entirety of the gate driver are implemented, with the output section 1504 including the half-bridge transistor circuit. The input section 1502 generates multiple square wave signals and provides the square wave signals to the output section 1504. The output section 1504 generates an amplified square waveform from the multiple square wave signals received from the input section 1502. The output section 1504 also shapes an envelope, such as a peak-to-peak magnitude, of the amplified square waveform. For example, a shaping control signal 1503 is supplied from the input section 1502 to the output section 1504 to generate the envelope. The shaping control signal 1503 has multiple voltage values for shaping the amplified square waveform to generate a shaped-amplified square waveform. For the first direct-drive RF signal generator 101A, the shaped-amplified square waveform is transmitted from the output section 1504 to the first reactive circuit 901. For the second direct-drive RF signal generator 101B, the shaped-amplified square waveform is transmitted from the output section 1504 to the second reactive circuit 1001.

Each of the first reactive circuit 901 and the second reactive circuit 1001 removes, such as filters out, higher-order harmonics of the shaped-amplified square waveform to generate a shaped-sinusoidal waveform having a fundamental frequency. In some embodiments, the first reactive circuit 901 and/or the second reactive circuit 1001 provides a reactance within a range extending from about −2500 ohms to about −10 ohms. The shaped-sinusoidal waveform has the same envelope as the shaped-amplified square waveform. For the first direct-drive RF signal generator 101A, RF power is transmitted from the first reactive circuit 901 to the outer coil 109O in the form of the shaped-sinusoidal waveform having the fundamental frequency. For the second direct-drive RF signal generator 101B, RF power is transmitted from the second reactive circuit 1001 to the inner coil 109I in the form of the shaped-sinusoidal waveform having the fundamental frequency. RF power transmitted to the inner coil 109I and/or outer coil 109O is transmitted into the plasma chamber 111 to transform one or more process gas(es) within the processing chamber 111 into the plasma 211 for processing of the substrate 203, as previously discussed with regard to FIG. 2B.

In some embodiments, for the first direct-drive RF signal generator 101A, a reactance of the first reactive circuit 901 is modified by transmitting a quality factor control signal 1507 from the input section 1502 to the first reactive circuit 901, where the quality factor control signal 1507 directs implementation of a specific change in the reactance of the first reactive circuit 901, such as by directing implementation of a change in the capacitance setting of the variable capacitor 801. In some embodiments, for the second direct-drive RF signal generator 101B, a reactance of the second reactive circuit 1001 is modified by transmitting the quality factor control signal 1507 from the input section 1502 to the second reactive circuit 1001, where the quality factor control signal 1507 directs implementation of a specific change in the reactance of the second reactive circuit 1001, such as by directing implementation of a change in the capacitance setting of the variable capacitor 811.

In some embodiments, a feedback signal 1505 is sent from an output O1 of the output section 1504 to the input section 1502. In some embodiments, a phase difference between the time-varying voltage and the time-varying current of the shaped-amplified square waveform output from the output section 1504 is determined from the feedback signal 1505 to enable control of the output section 1504 to reduce or eliminate the phase difference. In some embodiments, for the first direct-drive RF signal generator 101A, in addition to or instead of the feedback signal 1505, an optional feedback signal 1509 is transmitted from the output of the first reactive circuit 901 to the input section 1502. In some embodiments, a phase difference between the time-varying voltage and the time-varying current of the shaped-sinusoidal waveform output from the first reactive circuit 901 is determined from the feedback signal 1509 to enable control of the output section 1504 and/or first reactive circuit 901 to reduce or eliminate the phase difference. In some embodiments, for the second direct-drive RF signal generator 101B, in addition to or instead of the feedback signal 1505, the optional feedback signal 1509 is transmitted from the output of the second reactive circuit 1001 to the input section 1502. In some embodiments, a phase difference between the time-varying voltage and the time-varying current of the shaped-sinusoidal waveform output from the second reactive circuit 1001 is determined from the feedback signal 1509 to enable control of the output section 1504 and/or second reactive circuit 1001 to reduce or eliminate the phase difference.

FIG. 16 shows a flowchart of a method for delivering RF power from the direct-drive RF power supply 101 to the plasma processing chamber 111, in accordance with some embodiments. The method includes an operation 1601 for transmitting a shaped-amplified square waveform signal from an output of the first/second direct-drive RF signal generator 101A/101B to the reactive circuit 901/1001, where the reactive circuit 901/1001 operates to transform the shaped-amplified square waveform signal into the shaped-sinusoidal signal. In some embodiments, the direct-drive RF signal generator 101A/101B has a non-50 ohm output impedance. The method also includes an operation 1603 for transmitting the shaped-sinusoidal signal from an output of the reactive circuit 901/1001 to the coil 109O/109I of the plasma processing chamber 111. The shaped-sinusoidal signal conveys RF power to the coil 109O/109I. The method also includes an operation 1605 for adjusting a capacitance setting within the reactive circuit 901/1001 so that a peak amount of RF power is transmitted from the direct-drive radiofrequency signal generator 101A/101B through the reactive circuit 901/1001 to the coil 109O/109I.

In some embodiments, adjusting the capacitance setting in operation 1605 essentially cancels an inductive part of a load to which the direct-drive RF signal generator 101A/101B is connected by way of the coil 109O/109I so that the load is primarily a resistive load. In some embodiments, adjusting the capacitance setting in operation 1605 removes non-fundamental harmonic components of the shaped-amplified square waveform signal that is transmitted from the output of the direct-drive RF signal generator 101A/101B to the reactive circuit 901/1001. In some embodiments, the shaped-amplified square waveform signal output by the first direct-drive RF signal generator 101A has a frequency of about 2 megaHertz (MHZ) and the capacitance setting of the variable capacitor 801 in the first reactive circuit 901 is adjusted in the operation 1605 within a range extending from about 2500 picofarads (pF) to about 4500 pF. In some embodiments, the shaped-amplified square waveform signal output by the first direct-drive RF signal generator 101A has a frequency of about 2 MHz and the first reactive circuit 901 provides a reactance within a range extending from about −32 ohms to about −17 ohms. In some embodiments, the shaped-amplified square waveform signal output by the second direct-drive RF signal generator 101B has a frequency of about 13.56 megaHertz (MHZ) and the capacitance setting of the variable capacitor 811 in the second reactive circuit 1001 is adjusted in the operation 1605 within a range extending from about 5 pF to about 1000 pF. In some embodiments, the shaped-amplified square waveform signal output by the second direct-drive RF signal generator 101B has a frequency of about 13.56 MHz and the second reactive circuit 1001 provides a reactance within a range extending from about −2410 ohms to about −35 ohms.

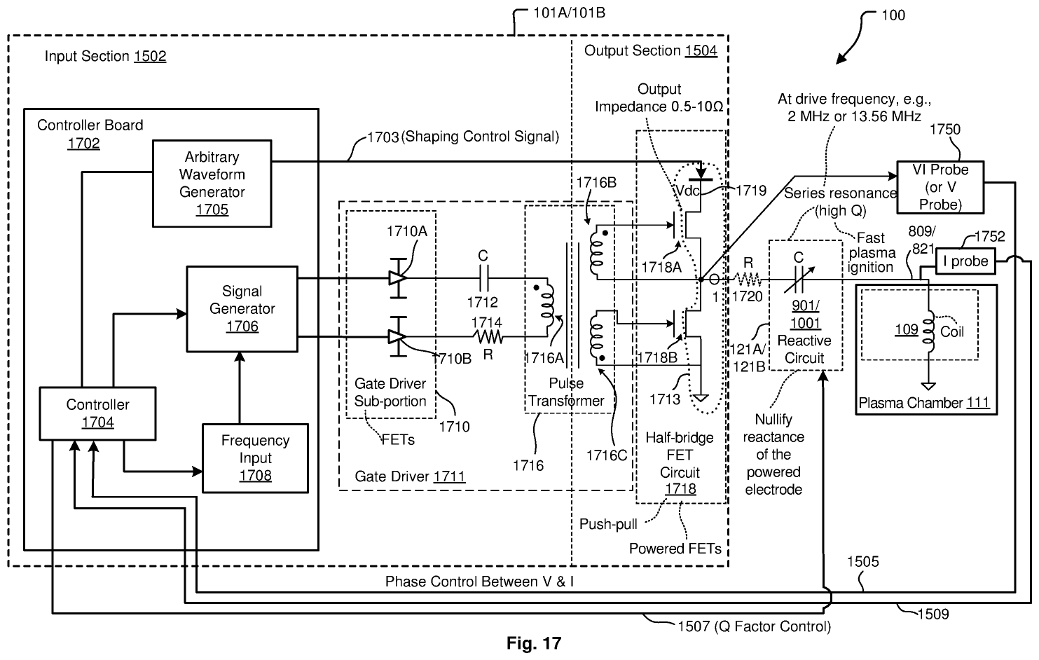

FIG. 17 shows a schematic diagram of each of the first and second direct-drive RF signal generators 101A/101B, in accordance with some embodiments. The input section 1502 includes a controller board 1702 and a portion of a gate driver 1711. The gate driver 1711 is coupled to the controller board 1702. The output section 1504 includes the remaining portion of the gate driver 1711 and a half-bridge field effect transistor (FET) circuit 1718. The half-bridge FET circuit 1718 or a tree, described below, is sometimes referred to herein as an amplification circuit and is coupled to the gate driver 1711.

The controller board 1702 includes a controller 1704, a signal generator 1706, and a frequency input 1708. In some embodiments, the controller 1704 includes a processor and a memory device. In some embodiments, the controller 1704 includes one or more of a microprocessor, an application specific integrated circuit (ASIC), a central processing unit, a processor, a programmable logic device (PLD), and a Field Programmable Gate Array (FPGA). The signal generator 1706 is a square wave oscillator that generates a square wave signal, such as a digital waveform or a pulse train. The square wave pulses between a first logic level, such as high (or one), and a second logic level, such as low (or zero). The signal generator 1706 generates the square wave signal at a prescribed operating frequency, such as 400 kiloHertz (kHz), or 2 MHz, or 13.56 MHz, or 27 MHz, or 60 MHz, among other operating frequencies.

The gate driver 1711 includes a first portion, which has a gate driver sub-portion 1710, a capacitor 1712, a resistor 1714, and a primary winding 1716A of a transformer 1716. The gate driver 1711 also includes a second portion (the remaining portion), which includes secondary windings 1716B and 1716C of the transformer 1716. The gate driver sub-portion 1710 includes multiple gate drivers 1710A and 1710B. Each of the gate drivers 1710A and 1710B is coupled to a positive voltage source at one end and to a negative voltage source at its opposite end. The half-bridge FET circuit 1718 includes a FET 1718A and a FET 1718B that are coupled to each other in a push-pull configuration. In some embodiments, such as shown in FIG. 17, the FETs 1718A and 1718B are n-type FETs that turn on when at least a threshold voltage is applied their gate conductor. However, in other embodiments, the FETs 1718A and 1718B are p-type FETs that turn off when at least a threshold voltage is applied their gate conductor. In some embodiments, each of the FET 1718A and the FET 1718B is implemented as a metal oxide semiconductor field effect transistor (MOSFET). In some embodiments, another type of transistor is used in place of the FETs 1718A and 1718A, such as an insulated gate bipolar transistor (IGBT), or a metal semiconductor field effect transistor (MESFET), or a junction field effect transistor (JFET), among others. In some embodiments, each of the FET 1718A and the FET 1718B is made from silicon carbide, or silicon, or gallium nitride. Each of the FET 1718A and the FET 1718B has an output impedance that lies within a pre-determined range, such as within a range extending from about 0.01 Ohm to about 10 Ohms. In some embodiments, the half-bridge FET circuit 1718 includes a direct current (DC) rail 1713 (illustrated within a dotted section), which includes a voltage source Vdc electrically connected to a first terminal of the FET 1718A through a conductor 1719. A second terminal of the FET 1718A is electrically connected to a first terminal of the FET 1718B. A second terminal of the FET 1718B is electrically connected to a reference ground potential.

In some embodiments, a voltage and current (VI) probe 1750 is coupled to the output O1 of the half-bridge FET circuit 1718. The VI probe 1750 is a sensor that measures a complex current at the output O1, a complex voltage at the output O1, and a phase difference between the complex voltage and the complex current. The complex current has a magnitude and a phase. Similarly, the complex voltage has a magnitude and a phase. The output O1 is between the source terminal of the FET 1718A and the drain terminal of the FET 1718B. The VI probe 1750 is coupled to the controller 1704 to transmit the feedback signal 1509. In some embodiments, a voltage (V) probe 1750 is used in place of the VI probe 1750. In these embodiments, a current (I) probe 1752 is coupled to the output of the first/second reactive circuit 901/1001. The V probe 1750 is a sensor that measures a time-varying complex voltage magnitude and phase at the output O1. The I probe 1752 is a sensor that measures a time-varying complex current magnitude and phase at the output of the first/second reactive circuit 901/1001.

The controller 1704 is coupled to the signal generator 1706 to provide the frequency input 1708, such as the operating frequency, to the signal generator 1706. The controller 1704 is further coupled through a conductor to the voltage source Vdc of the DC rail 1713. The signal generator 1706 is also coupled at its output to the gate drivers 1710A and 1710B. An output of the gate driver 1710A is coupled to the capacitor 1712. An output of the gate driver 1710B is coupled to the resistor 1714. The capacitor 1712 and the resistor 1714 are coupled to opposite ends of the primary winding 1716A of the transformer 1716. The capacitor 312 functions to cancel or negate an inductance of the primary winding 1716A. The cancellation or negation of the inductance of the primary winding 1716A facilitates generation of a square shape of the gate drive signals that are output by the gate drivers 1710A and 1710B. Also, the resistor 1714 reduces an oscillation of the square wave signal that is generated by the signal generator 1706.

A first end of the secondary winding 1716B of the transformer 1716 is electrically connected to a gate terminal of the FET 1718A. A second end of the secondary winding 1716B is electrically connected to both the second terminal of the FET 1718A and the first terminal of the FET 1718B, which are both electrically connected to the output O1 of the half-bridge FET circuit 1718.

A first end of the secondary winding 1716C of the transformer 1716 is electrically connected to a gate terminal of the FET 1718B. A second end of the secondary winding 1716C is electrically connected to the reference ground potential. The output O1 of the half-bridge FET circuit 1718 is electrically connected to the input of the first/second reactive circuit 901/1001. A resistance 1720 is seen by the output O1 of the half-bridge FET circuit 1718. The resistance 1720 represents a combination of the resistance in the portion of the coil assembly 109 to which the first/second direct-drive RF signal generator 101A/101B is connected, the resistance presented by the plasma 211 when present within the plasma processing chamber 111, and the resistance of the RF power transmission path from the output O1 to the coil assembly 109.

The controller 1704 generates a setting, such as the frequency input 1708, and provides the frequency input 1708 to the signal generator 1706. The frequency input 1708 is the value, such as 2 MHz or 13.56 MHz, of the target operating frequency. The signal generator 1706 generates an input RF signal having the target operating frequency upon receiving the setting from the controller 1704. The input RF signal is the square wave signal. The gate drivers 1710A and 1710B amplify the input RF signal to generate an amplified RF signal and provide the amplified RF signal to the primary winding 1716A of the transformer 1716.

Based on a directionality of electrical current flow of the amplified RF signal at a given time, either the secondary winding 1716B or the secondary winding 1716C generates a gate drive signal having a threshold voltage at the given time. For example, when the electrical current of the amplified RF signal flows from a positively charged terminal (indicated by a dot) of the primary winding 1716A to a negatively charged terminal (indicated by the absence of a dot) of the primary winding 1716A, the secondary winding 1716B generates a gate drive signal having at least the threshold voltage to turn on the FET 1718A, and the secondary winding 1716C does not generate the threshold voltage such that the FET 1718B is off. Conversely, when the current of the amplified RF signal flows from the negatively charged terminal (indicated by the absence of the dot) of the primary winding 1716A to the positively charged terminal (indicated by the dot) of the primary winding 1716A, the secondary winding 1716C generates a gate drive signal having at least the threshold voltage to turn on the FET 1718B, and the secondary winding 1716B does not generate the threshold voltage such that the FET 1718A is off.

Each gate drive signal that is transmitted to the gate of the FET 1718A and the gate of the FET 1718B is a square wave signal, e.g., a digital signal or a pulsed signal, having the target operating frequency. For example, each gate drive signal that is transmitted to the gate of the FET 1718A and the gate of the FET 1718B transitions between a low level and a high level. The gate drive signals that are transmitted to the gate of the FET 1718A and the gate of the FET 1718B have the target operating frequency and are in reverse synchronization with respect to each other. More specifically, during a time interval or a time at which the gate drive signal that is transmitted to the gate of the FET 1718A transitions from the low level to the high level, the gate drive signal that is transmitted to the gate of the FET 1718B simultaneously transitions from the high level to the low level. Similarly, during a time interval or a time in which the gate drive signal that is transmitted to the gate of the FET 1718A transitions from the high level to the low level, the gate drive signal that is transmitted to the gate of the FET 1718B simultaneously transitions from the low level to the high level. This reverse synchronization of the gate drive signals allows the FETs 1718A and 1718B to be turned on consecutively and to be turned off consecutively in a repeating manner in accordance with the target operating frequency of the time-varying square wave signal. The FETs 1718A and 1718B are consecutively operated. For example, when the FET 1718A is turned on, the FET 1718B is turned off. And, when the FET 1718B is turned on, the FET 1718A is turned off. The FETs 1718A and 1718B are not on at the same time or during the same time period. At frequencies other than the target operating frequency, the first/second reactive circuit 901/1001 functions to present a high load so that not much current will come out of the first/second direct-drive RF signal generator 101A/101B at the other non-target frequencies.

When the FET 1718A is on and the FET 1718B is off, electrical current flows between the voltage source Vdc and the output O1 to generate a voltage at the output O1. The voltage at the output O1 is generated according to the voltage values received from the controller 1704 or an arbitrary waveform generator 1705, which is further described below. When the FET 1718B is off, there is no electrical current flowing from the output O1 to the ground potential that is coupled to the FET 1718B. Electrical current flows from the voltage source Vdc through the output O1 to the input of the first/second reactive circuit 901/1001 when the FET 1718A is on. Also, when the FET 1718B is on and the FET 1718A is off, electrical current flows from the output O1 to the reference ground potential coupled to the FET 1718B. When the FET 1718A is off, there is no electrical current flowing from the voltage source Vdc to the output O1.

In some embodiments, the controller 1704 directs the arbitrary waveform generator 1705 to generate the shaping control signal 1703 that indicates voltage values. The shaping control signal 1703 is transmitted through an electrical conductor to the voltage source Vdc. The DC rail 1713 is agile in that there is fast control of the voltage source Vdc by the controller 1704 (and, optionally, by the arbitrary waveform generator 1705). Both the controller 1704 and the voltage source Vdc are electronic circuits, which allow the controller 1704 to substantially instantaneously control the voltage source Vdc. For example, at a time the controller 1704 sends (cither directly or by way of the arbitrary waveform generator 1705) the voltage values in the shaping control signal 1703 to the voltage source Vdc, the voltage source Vdc substantially instantaneously changes its output voltage level accordingly. In some embodiments, the voltage values indicated by the shaping control signal 1703 are within a range extending from about zero volt to about 80 volts, such that the DC rail 1713 operates within this voltage range. The voltage values indicated by the shaping control signal 1703 are magnitudes of the voltage signal that is generated by the voltage source Vdc to define the shaped envelope of the shaped-amplified square waveform at the output O1 of the output section 1504. For example, when the first/second direct-drive RF signal generator 101A/101B is operated to generate a continuous waveform, the voltage values indicated by the shaping control signal 1703 control, as a function of time, a peak-to-peak magnitude of a parameter of the continuous waveform generated at the output O1 of the output section 1504, where the parameter is one or more of power, voltage, and current, by way of example. The peak-to-peak magnitude of the continuous waveform defines the shaped envelope of the continuous waveform as a function of time.

In another example, when the first/second direct-drive RF signal generator 101A/101B is operated to generate the shaped-amplified square waveform at the output O1 to have a shaped envelope that is pulsed shape, the voltage values indicated by the shaping control signal 1703 are changed substantially instantaneously (in a step-function-like manner) at a given time or during a given pre-determined time period, such that the peak-to-peak magnitude of the shaped-amplified square waveform changes from a first parameter level (e.g., high level) to a second parameter level (e.g., low level) or changes from the second parameter level to the first parameter level, where the parameter is one or more of power, voltage, and current, by way of example. In another example, when the first/second direct-drive RF signal generator 101A/101B is operated to generate the shaped-amplified square waveform at the output O1 to have a shaped envelope that is of arbitrary shape, the voltage values indicated by the shaping control signal 1703 are changed in a prescribed and controlled arbitrary manner as directed by the controller 1704 by way of the arbitrary waveform generator 1705, such that the peak-to-peak magnitude of the shaped-amplified square waveform changes is the prescribed and controlled arbitrary manner. In another example, when the first/second direct-drive RF signal generator 101A/101B is operated to generate the shaped-amplified square waveform at the output O1 to have a multi-state pulsed shape, the voltage values indicated by the shaping control signal 1703 are changed substantially instantaneously (in a step-function-like manner) at a given time or during a given pre-determined time period, such that the peak-to-peak magnitude of the shaped-amplified square waveform changes between different states, where each of the different states has a different peak-to-peak magnitude of particular parameter level, e.g., power level, voltage level, and/or current level, among others. In various embodiments, the number of different states is two or more, as specified by the controller 1704.

The shaped-amplified square waveform generated at the output O1 of the output section 1504 is based on operation (as a function of time) of the FETs 1718A and 1718B in accordance with the gate drive signals as output by the gate drivers 1710A and 1710B, and supply (as a function of time) of voltage by the voltage source Vdc in accordance with the shaping control signal 1703. An amount of amplification of the shaped-amplified square waveform is based on the output impedances of the FETs 1718A and 1718B of the half-bridge FET circuit 1718, the voltage values that are supplied by the controller 1704 (and, optionally, by the arbitrary waveform generator 1705) to the voltage source Vdc, and a maximum achievable voltage value of the voltage source Vdc. The first/second reactive circuit 901/1001 receives the shaped-amplified square waveform and functions to reduce or eliminate the higher-order harmonics of the shaped-amplified square waveform to generate the shaped-sinusoidal waveform having a fundamental frequency. It should be understood that the shaped-sinusoidal waveform that is output by the first/second reactive circuit 901/1001 has the same shaped envelope as the shaped-amplified square waveform that is input to the first/second reactive circuit 901/1001. The shaped-sinusoidal waveform that is output by the first/second reactive circuit 901/1001 is provided to the coil assembly 109 as an RF signal for generation of the plasma 211 within the plasma processing chamber 111.

The VI probe 1750 measures the complex voltage and complex current of the shaped-amplified square waveform at the output O1 and provides the feedback signal 1505 to the controller 1704, where the feedback signal 1505 indicates the complex voltage and complex current. The controller 1704 identifies the phase difference between the complex voltage of the shaped-amplified square waveform and the complex current of the shaped-amplified square waveform from the feedback signal 1505, and determines whether the phase difference is within a predetermined acceptable range. For example, the controller 1704 determines whether or not the phase difference is zero or within a predetermined acceptable range (percentage) away from zero. Upon determining that the phase difference is not within the predetermined acceptable range, the controller 1704 changes frequency values of the operating frequency to change the frequency input 1708. The changed frequency values are provided from the frequency input 1708 to the signal generator 1706 to change the operating frequency of the signal generator 1706. In some embodiments, the operating frequency is changed in less than or equal to about 10 microseconds. The operating frequency of the signal generator 1706 is changed until the controller 1704 determines that the phase difference between the complex voltage and the complex current that is measured by the VI probe 1750 is within the predetermined acceptable range. Upon determining that the phase difference between the complex voltage and the complex current is within the predetermined acceptable range, the controller 1704 does not further change the frequency input 1708. When the phase difference is within the predetermined acceptable range, a predetermined amount of power is provided from the output O1 of the first/second direct-drive RF signal generator 101A/101B through the first/second reactive circuit 901/1001 to the coil assembly 109.

In some embodiments, in addition to or instead of changing the frequency input 1708, the controller 1704 changes the voltage values in the shaping control signal 1703 that is being supplied to the voltage source Vdc in order to change the voltage signal generated by the voltage source Vdc. The voltage source Vdc changes its voltage level in accordance with the voltage values indicated in the shaping control signal 1703. The controller 1704 continues to change the voltage values in the shaping control signal 1703 until the shaped-amplified square waveform achieves a predetermined power setpoint. In some embodiments, the predetermined power setpoint is stored in a memory device of the controller 1704. In various embodiments, instead of changing a voltage of the shaped-amplified square waveform at the output O1, a current of the shaped-amplified square waveform is changed. For example, by directing changes in the voltage values in the shaping control signal 1703, the controller 1704 changes the current of the shaped-amplified square waveform at the output O1 until the shaped-amplified square waveform achieves a predetermined current setpoint. In some embodiments, the predetermined current setpoint is stored in the memory device of the controller 1704. In some embodiments, instead of changing a voltage or a current of the shaped-amplified square waveform at the output O1, a power of the shaped-amplified square waveform is changed. For example, by directing changes in the voltage values in the shaping control signal 1703, the controller 1704 changes the power of the shaped-amplified square waveform at the output O1 until the shaped-amplified square waveform achieves a predetermined power setpoint. In some embodiments, the predetermined power setpoint is stored in the memory device of the controller 1704. It should be noted that any change in the voltage, current, or power of the shaped-amplified square waveform generated at the output O1 produces the same change in the voltage, current, or power, respectively, of the shaped-sinusoidal waveform that is output by the first/second reactive circuit 901/1001.

In some embodiments, the controller 1704 is coupled through a motor driver and a motor (e.g., stepper motor) to the first/second reactive circuit 901/1001. In some embodiments, the motor driver is implemented as an integrated circuit device that includes one or more transistors. The controller 1704 sends a signal, such as the quality factor control signal 1507, to the motor driver to generate an electrical signal that is transmitted from the motor driver to the motor. The motor operates in accordance with the electrical signal received from the motor driver to change a reactance of the first/second reactive circuit 901/1001. For example, in some embodiments, the motor operates to change an area (or spacing) between electrically conducive plates within the capacitor 801/811 to change the reactance of the first/second reactive circuit 901/1001. In some embodiments, the reactance of the first/second reactive circuit 901/1001 is changed to maintain a prescribed quality factor of the first/second reactive circuit 901/1001.

The first/second reactive circuit 901/1001 in combination with an inductance of the outer/inner coil 109O/109I has a high quality factor (Q). For example, an amount of power of the shaped-amplified square waveform generated at the output O1 that is lost in the first/second reactive circuit 901/1001 is low compared to an amount of power of the shaped-sinusoidal waveform that is transmitted from the output of the first/second reactive circuit 901/1001 to the outer/inner coil 109O/109I. The high quality factor of the first/second reactive circuit 901/1001 facilitates fast ignition of the plasma 211 within the plasma processing chamber 111. Also, the first/second reactive circuit 901/1001 is configured and set to resonate out an inductive reactance of the outer/inner coil 109O/109I and the plasma 211, such that the output O1 of the first/second direct-drive RF signal generator 101A/101B sees the resistance 1720 but does not see essentially any reactance. For example, the first reactive circuit 901 is controlled to have a reactance that reduces, such as nullifies or cancels, a reactance of one or more of the outer coil 109O, the plasma 211, and the RF power transmission connections between the first reactive circuit 901 and the outer coil 109O. In some embodiments, the reactance of the first reactive circuit 901 is controlled by controlling the capacitance setting of the variable capacitor 801. Similarly, the second reactive circuit 1001 is controlled to have a reactance that reduces, such as nullifies or cancels, a reactance of one or more of the inner coil 109I, the plasma 211, and the RF power transmission connections between the second reactive circuit 1001 and the inner coil 109I. In some embodiments, the reactance of the second reactive circuit 1001 is controlled by controlling the capacitance setting of the variable capacitor 811.

In some embodiments, the FETs 1718A and 1718B are fabricated from silicon carbide to have a low internal resistance and fast switching time, and to facilitate cooling of the FETs 1718A and 1718B. The low internal resistance of the FETs 1718A and 1718B provides for higher efficiency, which enables the FETs 1718A and 1718B to turn on nearly instantaneously and to turn off fast, such as in less than 10 microseconds. In some embodiments, each of the FETs 1718A and 1718B is configured to turn on and off in less than a pre-determined time period, such as less than 10 microseconds. In some embodiments, each of the FETs 1718A and 1718B is configured to turn on and off in a time period extending from about 0.5 microsecond to about 10 microseconds. In some embodiments, each of the FETs 1718A and 1718B is configured to turn on and off in a time period extending from about 1 microsecond to about 5 microseconds. In some embodiments, each of the FETs 1718A and 1718B is configured to turn on and off in a time period extending from about 3 microseconds to about 7 microseconds. It should be understood that there is essentially no delay in transition between the on and off states for each of the FETs 1718A and 1718B. In this manner, when the FET 1718A turns on, the FET 1718B essentially simultaneously turns off. And, when the FET 1718A turns off, the FET 1718B essentially simultaneously turns on. The FETs 1718A and 1718B are configured to switch on and off fast enough to ensure that the FETs 1718A and 1718B will not be on at the same time in order to avoid electrical current flow directly from the voltage source Vdc to the reference ground potential through the FETs 1718A and 1718B.

The low internal resistance of the silicon carbide FETs 1718A and 1718B reduces an amount of heat generated by the silicon carbide FETs 1718A and 1718B, which makes it easier to cool the silicon carbide FETs 1718A and 1718B using a cooling plate or a heat sink.

It should be understood that the components, such as transistors, of the first/second direct-drive RF signal generator 101A/101B are electronic. Also, it should be understood that there is no RF impedance matching network and RF transmission line in the RF power transmission path from the first/second direct-drive RF signal generator 101A/101B to the coil assembly 109. The electronic components within the first/second direct-drive RF signal generator 101A/101B in combination with the absence of the RF impedance matching network and RF transmission line in the RF power transmission path from the first/second direct-drive RF signal generator 101A/101B to the coil assembly 109 provides for repeatability and consistency in regard to fast plasma 211 ignition and plasma 211 sustainability across different plasma processing chambers 111.

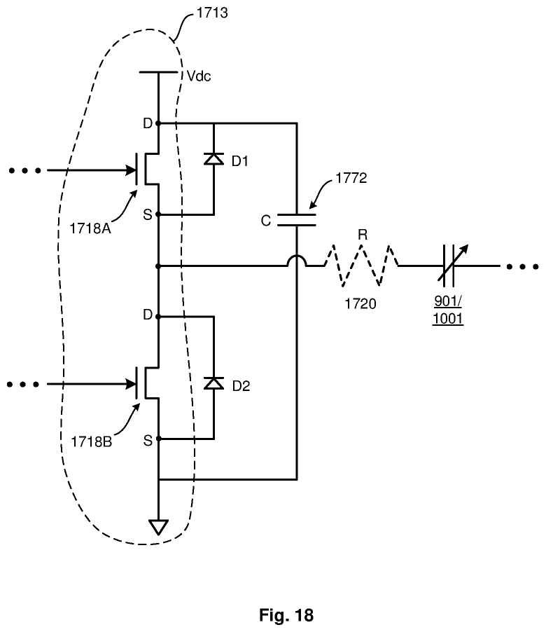

FIG. 18 shows a circuit schematic of the half-bridge FET circuit 1718 that implements voltage limiters across the FETs 1718A and 1718B, in accordance with some embodiments. A diode D1 is connected between the drain terminal (D) and the source terminal(S) of the FET 1718A to limit voltage across the FET 1718A. When the FET 1718A is turned on and the FET 1718B is turned off, voltage across the FET 1718A increases until the voltage is limited by the diode D1. The diode D1 functions to prevent electrical current from adversely shooting through the FET 1718A directly from the voltage source Vdc to the reference ground potential. Similarly, a diode D2 is connected between the drain terminal (D) and the source terminal(S) of the FET 1718B to limit voltage across the FET 1718B. When the FET 1718B is turned on and the FET 1718A is turned off, voltage across the FET 1718B increases until the voltage is limited by the diode D2. The diode D2 functions to prevent electrical current from adversely shooting through the FET 1718B directly from the voltage source Vdc to the reference ground potential. A capacitor 1772 is connected between the drain terminal (D) of the FET 1718A and the source terminal(S) of the FET 1718B. In the event of a delay in turning off and on of the FET 1718A and/or 1718B, electrical current will flow from the voltage source Vdc through the capacitor 1772 to the reference ground potential to reduce the probability of having an adverse and potentially damaging amount of electrical current flow through the output O1 of the first/second direct-drive RF signal generator 101A/101B to the coil assembly 109.

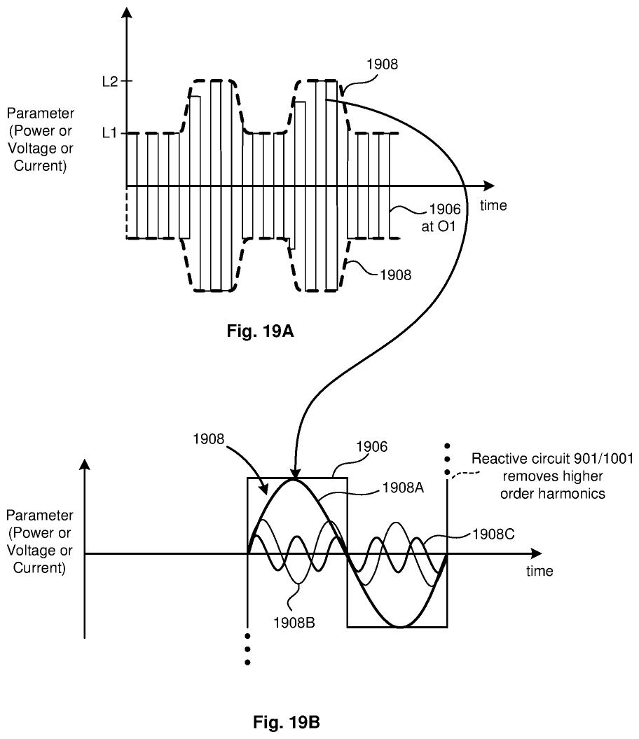

FIG. 19A shows a plot of a parameter of an example shaped-amplified square waveform 1906 generated at the output O1 of the first/second direct-drive RF signal generator 101A/101B as a function of time, in accordance with some embodiments. The parameter of the shaped-amplified square waveform 1906 is either power, voltage, or current. The shaped-amplified square waveform 1906 has a shaped envelope 1908 generated in accordance with the voltage values indicated by the shaping control signal 1703 as directed by the controller 1704 and/or arbitrary waveform generator 1705. The shaped envelope 1908 is controlled so that an absolute magnitude of the parameter of the shaped-amplified square waveform 1906 transitions between a first level L1 (lower level) and a second level L2 (higher level). The parameter has a lower peak-to-peak magnitude at the first level L1 than at the second level L2. It should be understood that the shaped envelope 1908 can have a different shape than what is shown in FIG. 19A, depending on the voltage values indicated by the shaping control signal 1703. For example, the shaping control signal 1703 can be generated to direct the shaped envelope 1908 to have a continuous wave shape, a triangular shape, a multi-level pulse shape, or essentially any other prescribed controlled arbitrary shape.

FIG. 19B shows a plot of a parameter of an example shaped-sinusoidal waveform 1908 generated at the output of the first/second reactive circuit 901/1001 as a function of time, in accordance with some embodiments. The parameter of the shaped-sinusoidal waveform 1908 is either power, voltage, or current. The shaped-sinusoidal waveform 1908 is based on the shaped-amplified square waveform 1906 that is input to the first/second reactive circuit 901/1001 as a function of time. The shaped-amplified square waveform 1906 is a combination of a fundamental frequency sinusoidal waveform 1908A and multiple higher-order harmonic frequency sinusoidal waveforms 1908B, 1908C, etc. For example, the sinusoidal waveform 1908B represents a second order harmonic frequency of the fundamental frequency sinusoidal waveform 1908A. And, the sinusoidal waveform 1908C represents a third order harmonic frequency of the fundamental frequency sinusoidal waveform 1908A. The first/second reactive circuit 901/1001 functions to remove the higher-order harmonic frequency sinusoidal waveforms 1908B, 1908C from the shaped-amplified square waveform 1906, so that just the fundamental frequency sinusoidal waveform 1908A is provided at the output of the first/second reactive circuit 901/1001 as a function of time. The high quality factor of the first/second reactive circuit 901/1001 facilitates removal of the higher-order harmonic frequency sinusoidal waveforms 1908B, 1908C, etc. from the shaped-amplified square waveform 1906 that is output by the first/second direct-drive RF signal generator 101A/101B. The fundamental frequency sinusoidal waveform 1908A is transmitted as the shaped-sinusoidal waveform 1908 to the coil assembly 109, thereby transmitting RF power to the coil assembly 109.

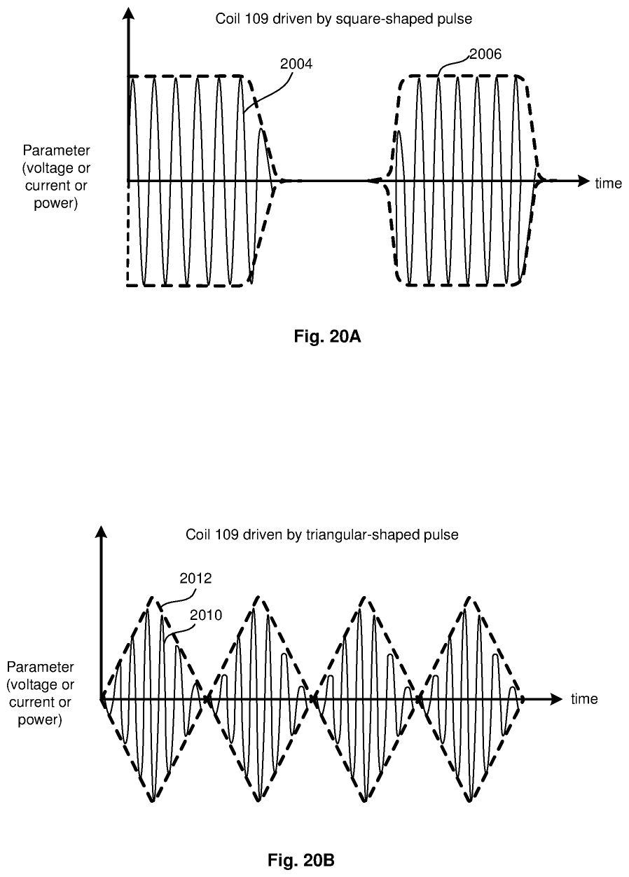

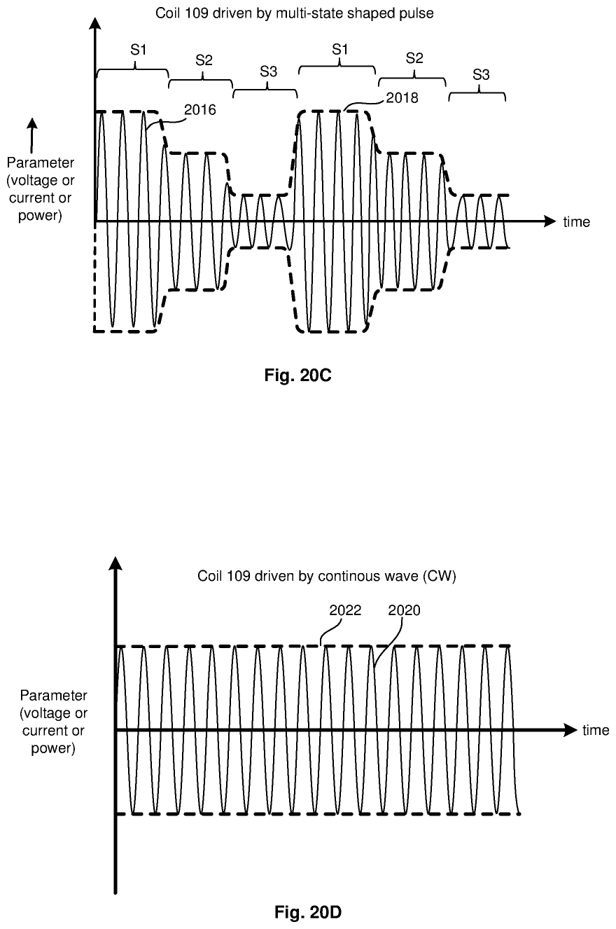

FIG. 20A shows a plot of a parameter of an example shaped-sinusoidal waveform 2004 generated at the output of the first/second reactive circuit 901/1001 as a function of time, in accordance with some embodiments. The parameter of the shaped-sinusoidal waveform 2004 is either power, voltage, or current. The shaped-sinusoidal waveform 2004 has a shaped envelope 2006 generated in accordance with the voltage values indicated by the shaping control signal 1703 as directed by the controller 1704 and/or arbitrary waveform generator 1705. The shaped envelope 2006 defines a peak-to-peak change in the parameter of the shaped-sinusoidal waveform 2004 as a function of time. The example shaped envelope 2006 represents a square-shaped envelope, such as a pulse shaped envelope.

FIG. 20B shows a plot of a parameter of an example shaped-sinusoidal waveform 2010 generated at the output of the first/second reactive circuit 901/1001 as a function of time, in accordance with some embodiments. The parameter of the shaped-sinusoidal waveform 2010 is either power, voltage, or current. The shaped-sinusoidal waveform 2010 has a shaped envelope 2012 generated in accordance with the voltage values indicated by the shaping control signal 1703 as directed by the controller 1704 and/or arbitrary waveform generator 1705. The shaped envelope 2012 defines a peak-to-peak change in the parameter of the shaped-sinusoidal waveform 2010 as a function of time. The example shaped envelope 2010 represents a triangular-shaped envelope.

FIG. 20C shows a plot of a parameter of an example shaped-sinusoidal waveform 2016 generated at the output of the first/second reactive circuit 901/1001 as a function of time, in accordance with some embodiments. The parameter of the shaped-sinusoidal waveform 2016 is either power, voltage, or current. The shaped-sinusoidal waveform 2016 has a shaped envelope 2018 generated in accordance with the voltage values indicated by the shaping control signal 1703 as directed by the controller 1704 and/or arbitrary waveform generator 1705. The shaped envelope 2018 defines a peak-to-peak change in the parameter of the shaped-sinusoidal waveform 2016 as a function of time. The example shaped envelope 2018 represents a multi-state shaped envelope that includes three different states S1, S2, and S3. The shaped envelope 2018 is defined so that the peak-to-peak change in the parameter of the shaped-sinusoidal waveform 2016 during the first state S1 is greater than the peak-to-peak change in the parameter of the shaped-sinusoidal waveform 2016 during the first state S2. The shaped envelope 2018 is also defined so that the peak-to-peak change in the parameter of the shaped-sinusoidal waveform 2016 during the second state S2 is greater than the peak-to-peak change in the parameter of the shaped-sinusoidal waveform 2016 during the third state S3. The shaped envelope 2018 revert back to the first state S1 after the third state S3. The states S1, S2, and S3 repeat at a frequency that is less than the frequency of the shaped-amplified square waveform that is output by the first/second direct-drive RF signal generator 101A/101B. Therefore, the states S1, S2, and S3 repeat at a frequency that is less than the frequency of the shaped-sinusoidal waveform 2016. In various embodiments, the multi-state shaped envelope includes more than three different states, with each different state corresponding to a different peak-to-peak change in the parameter of the shaped-sinusoidal waveform 2016 as a function of time. Also, in various embodiments, the multi-state shaped envelope can be controlled so that any of the three or more different states of the shaped envelope has cither a lower or higher peak-to-peak magnitude of the parameter of the shaped-sinusoidal waveform 2016 relative to a next state of the shaped envelope.

FIG. 20D shows a plot of a parameter of an example shaped-sinusoidal waveform 2020 generated at the output of the first/second reactive circuit 901/1001 as a function of time, in accordance with some embodiments. The parameter of the shaped-sinusoidal waveform 2020 is either power, voltage, or current. The shaped-sinusoidal waveform 2020 has a shaped envelope 2022 generated in accordance with the voltage values indicated by the shaping control signal 1703 as directed by the controller 1704 and/or arbitrary waveform generator 1705. The shaped envelope 2022 defines a peak-to-peak change in the parameter of the shaped-sinusoidal waveform 2020 as a function of time. The example shaped envelope 2022 is flat, such that shaped-sinusoidal waveform 2020 represents a continuous wave signal.

In various embodiments disclosed herein, an RF junction system is provided for transmission of RF power to the plasma processing chamber 111. The RF junction system includes a first terminal (such as the connection structure 805/817) configured to connect to an RF supply signal pin (such as the first/second lower RF connection structure 705A/705B), where the RF supply signal pin is electrically connected to the output of the first/second direct-drive RF signal generator 101A/101B. The RF junction system also includes a second terminal (such as the connection structure 807/818) configured to connect to the outer/inner coil 109O/109I. In some embodiments, the second terminal is connected to multiple separate windings of the outer/inner coil 109O/109I. The RF junction system also includes the first/second reactive circuit 901/1001 connected between the first terminal and the second terminal. The first/second reactive circuit 901/1001 is configured to transform a shaped-amplified square waveform signal into a shaped-sinusoidal signal in route from the first terminal to the second terminal.

In some embodiments, the first direct-drive RF signal generator 101A is configured to supply the shaped-amplified square waveform signal having a frequency of about 2 MHZ. In some of these embodiments, the first reactive circuit 901 is configured to provide a capacitance between the first terminal and the second terminal within a range extending from about 2500 pF to about 4500 pF. In some embodiments, the first reactive circuit 901 includes the variable capacitor 801 and the fixed capacitor 803 connected in parallel with each other. In some embodiments, a capacitance setting of the variable capacitor 801 is adjustable within a range extending from about 100 pF to about 2000 pF, and a capacitance of the fixed capacitor 803 is within a range extending from about 2000 pF to about 3500 pF.

In some embodiments, the second direct-drive RF signal generator 101B is configured to supply the shaped-amplified square waveform signal having a frequency of about 13.56 MHZ. In some of these embodiments, the second reactive circuit 1001 includes the variable capacitor 811 to provide a capacitance between the first terminal and the second terminal within a range extending from about 5 pF to about 1000 pF. Also, in some of these embodiments, the second junction box 121B includes the capacitor 813 connected a ground return end of the inner coil 109I and the reference ground potential 903. In some of these embodiments, the capacitor 813 has a capacitance within a range extending from about 200 pF to about 500 pF.

In various embodiments disclosed herein, an RF power transmission system is provided for the plasma processing chamber 111. The RF power transmission system includes the first/second direct-drive radiofrequency signal generator 101A/101B, the outer/inner coil 109O/109I, and the first/second reactive circuit 901/1001. The first/second direct-drive RF signal generator 101A/101B has a non-50 ohm output impedance. The first/second reactive circuit 901/1001 is connected between the output O1 of the first/second direct-drive RF signal generator 101A/101B and the outer/inner coil 109O/109I. The first/second reactive circuit 901/1001 is connected to receive a shaped-amplified square waveform signal from the output O1 of the first/second direct-drive radiofrequency signal generator 901/1001. The first/second reactive circuit 901/1001 is configured to transform the shaped-amplified square waveform signal into a shaped-sinusoidal signal in route from the first/second direct-drive RF signal generator 101A/101B to the outer/inner coil 109O/109I.

The first reactive circuit 901 includes the variable capacitor 801 having a capacitance set so that a peak amount of RF power is transmitted from the first direct-drive RF signal generator 101A through the reactive circuit 901 to the outer coil 109O. The first reactive circuit 901 is configured to essentially cancel an inductive part of a load to which the first direct-drive RF signal generator 101A is connected by way of the outer coil 109O so that the load is primarily a resistive load. The first reactive circuit 901 is configured to remove non-fundamental harmonic components of the shaped-amplified square waveform signal received from the first direct-drive RF signal generator 101A. In some embodiments, the shaped-amplified square waveform signal output by the first direct-drive RF signal generator 101A has a frequency of about 2 MHz and the first reactive circuit 901 provides a capacitance between the output O1 of the first direct-drive RF signal generator 101A and the outer coil 109O within a range extending from about 2500 pF to about 4500 pF.

The second reactive circuit 1001 includes the variable capacitor 811 having a capacitance set so that a peak amount of RF power is transmitted from the second direct-drive RF signal generator 101B through the reactive circuit 1001 to the inner coil 109I. The second reactive circuit 1001 is configured to essentially cancel an inductive part of a load to which the second direct-drive RF signal generator 101B is connected by way of the inner coil 109I so that the load is primarily a resistive load. The second reactive circuit 1001 is configured to remove non-fundamental harmonic components of the shaped-amplified square waveform signal received from the second direct-drive RF signal generator 101B. In some embodiments, the shaped-amplified square waveform signal output by the second direct-drive RF signal generator 101B has a frequency of about 13.56 MHz and the second reactive circuit 1001 includes the variable capacitor 811 set to provide a capacitance between the output O1 of the second direct-drive RF signal generator 101B and the inner coil 109I within a range extending from about 5 pF to about 1000 pF.

The various embodiments described herein may be practiced in conjunction with various computer system configurations including hand-held hardware units, microprocessor systems, microprocessor-based or programmable consumer electronics, minicomputers, mainframe computers and the like. The various embodiments described herein can also be practiced in conjunction with distributed computing environments where tasks are performed by remote processing hardware units that are linked through a computer network.

In some embodiments, a control system, e.g., host computer system, is provided for controlling the plasma processing system 100. In various embodiments, the plasma processing system 100 includes semiconductor processing equipment, such as processing tool(s), chamber(s), platform(s) for processing, and/or specific processing components such as a wafer pedestal, a gas flow system, among other components. In various embodiments, the plasma processing system 100 is integrated with electronics for controlling its operation before, during, and after processing of a semiconductor wafer or substrate, where the electronics are implemented within a controller that is configured and connected to control various components and/or sub-parts of the plasma processing system 100. Depending on substrate/wafer processing requirements and/or the particular configuration of the plasma processing system 100, the controller is programmed to control any process and/or component disclosed herein, including a delivery of process gas(es), temperature settings (e.g., heating and/or cooling), pressure settings, vacuum settings, power settings, first/second direct-drive RF signal generator 101A/101B settings, first/second reactive circuit 901/1001 settings, electrical signal frequency settings, gas flow rate settings, fluid delivery settings, positional and operation settings, substrate/wafer transfers into and out of the plasma generation chamber 111 and/or into and out of load locks connected to or interfaced with the plasma processing system 100.

Broadly speaking, in a variety of embodiments, the controller that is connected to control operations of the plasma processing system 100 is defined as electronics having various integrated circuits, logic, memory, and/or software that direct and control various tasks/operations, such as receiving instructions, issuing instructions, controlling device operations, enabling cleaning operations, enabling endpoint measurements, enabling metrology measurements (optical, thermal, electrical, etc.), among other tasks/operations. In some embodiments, the integrated circuits within the controller include one or more of firmware that stores program instructions, a digital signal processors (DSP), an Application Specific Integrated Circuit (ASIC) chip, a programmable logic device (PLD), one or more microprocessors, and/or one or more microcontrollers that execute program instructions (e.g., software), among other computing devices. In some embodiments, the program instructions are communicated to the controller in the form of various individual settings (or program files), defining operational parameters for carrying out a process on a substrate/wafer within the plasma processing system 100. In some embodiments, the operational parameters are included in a recipe defined by process engineers to accomplish one or more processing steps during the fabrication of one or more layers, materials, metals, oxides, silicon, silicon dioxide, surfaces, circuits, and/or dies on the substrate/wafer.

In some embodiments, the controller is a part of, or connected to, a computer that is integrated with, or connected to, the plasma processing system 100, or that is otherwise networked to the plasma processing system 100, or a combination thereof. For example, in some embodiments, the controller is implemented in a “cloud” or all or a part of a fab host computer system, which allows for remote access for control of substrate/wafer processing by the plasma processing system 100. The controller enables remote access to the plasma processing system 100 to provide for monitoring of current progress of fabrication operations, provided for examination of a history of past fabrication operations, provide for examination of trends or performance metrics from a plurality of fabrication operations, provide for changing of processing parameters, provide for setting of subsequent processing steps, and/or provide for initiation of a new substrate/wafer fabrication process.

In some embodiments, a remote computer, such as a server computer system, provides process recipes to the controller of the plasma processing system 100 over a computer network, which includes a local network and/or the Internet. The remote computer includes a user interface that enables entry or programming of parameters and/or settings, which are then communicated to the controller of the plasma processing system 100 from the remote computer. In some examples, the controller receives instructions in the form of settings for processing a substrate/wafer within the plasma processing system 100. It should be understood that the settings are specific to a type of process to be performed on a substrate/wafer and a type of tool/device/component that the controller interfaces with or controls. In some embodiments, the controller is distributed, such as by including one or more discrete controllers that are networked together and synchronized to work toward a common purpose, such as operating the plasma processing system 100 to perform a prescribed process on a substrate/wafer. An example of a distributed controller for such purposes includes one or more integrated circuits on a chamber in communication with one or more integrated circuits located remotely (such as at a platform level or as part of a remote computer) that combine to control a process in a chamber. Depending on a process operation to be performed by the plasma processing system 100, the controller communicates with one or more of other tool circuits or modules, other tool components, cluster tools, other tool interfaces, adjacent tools, neighboring tools, tools located throughout a factory, a main computer, another controller, or tools used in material transport that bring containers of substrates/wafers to and from tool locations and/or load ports in a semiconductor manufacturing factory.

It should be understood that, in some embodiments, operation of the plasma processing system 100 includes performance of various computer-implemented operations involving data stored in computer systems. These computer-implemented operations are those that manipulate physical quantities. In various embodiments, the computer-implemented operations are performed by either a general purpose computer or a special purpose computer. In some embodiments, the computer-implemented operations are performed by a selectively activated computer, and/or are directed by one or more computer programs stored in a computer memory or obtained over a computer network. When computer programs and/or digital data is obtained over the computer network, the digital data may be processed by other computers on the computer network, e.g., a cloud of computing resources. The computer programs and digital data are stored as computer-readable code on a non-transitory computer-readable medium. The non-transitory computer-readable medium is any data storage hardware unit, e.g., a memory device, etc., that stores data, which is thereafter readable by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), digital video/versatile disc (DVD), magnetic tapes, and other optical and non-optical data storage hardware units. In some embodiments, the computer programs and/or digital data are distributed among multiple computer-readable media located in different computer systems within a network of coupled computer systems, such that the computer programs and/or digital data is executed and/or stored in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments.

What is claimed is:

1. A junction system for a radiofrequency power transmission system for a plasma processing chamber, comprising:
a first terminal configured to connect to a radiofrequency signal supply pin that is connected to an output of a direct-drive radiofrequency signal generator;
a second terminal configured to connect to a coil; and
a reactive circuit connected between the first terminal and the second terminal, the reactive circuit configured to transform a shaped-amplified square waveform signal into a shaped-sinusoidal signal in route from the first terminal to the second terminal.

2. The junction system as recited in claim 1, wherein the reactive circuit provides a reactance within a range extending from about −2500 ohms to about −10 ohms.

3. The junction system as recited in claim 1, wherein the reactive circuit provides a capacitance between the first terminal and the second terminal within a range extending from about 2500 picofarads to about 4500 picofarads.

4. The junction system as recited in claim 3, wherein the direct-drive radiofrequency signal generator is configured to supply the shaped-amplified square waveform signal having a frequency of about 2 megahertz.

5. The junction system as recited in claim 1, wherein the reactive circuit includes a variable capacitor and a fixed capacitor connected in parallel with each other.

6. The junction system as recited in claim 5, wherein a capacitance setting of the variable capacitor is adjustable within a range extending from about 100 picofarads to about 2000 picofarads.

7. The junction system as recited in claim 5, wherein a capacitance of the fixed capacitor is within a range extending from about 2000 picofarads to about 3500 picofarads.

8. The junction system as recited in claim 1, wherein the reactive circuit provides a capacitance between the first terminal and the second terminal within a range extending from about 5 picofarads to about 1000 picofarads.

9. The junction system as recited in claim 8, wherein the direct-drive radiofrequency signal generator is configured to supply the shaped-amplified square waveform signal having a frequency of about 13.56 megahertz.

10. The junction system as recited in claim 8, further comprising:
a capacitor connected between a ground return end of the coil and a reference ground potential.

11. The junction system as recited in claim 10, wherein the capacitor has a capacitance within a range extending from about 200 picofarads to about 500 picofarads.

12. The junction system as recited in claim 1, wherein the second terminal is connected to multiple separate windings of the coil.

13. The junction system as recited in claim 1, wherein the reactive circuit includes a variable capacitor, and wherein the junction system includes a capacitance setting control connected to the variable capacitor, the capacitance setting control enabling adjustment of a capacitance setting of the variable capacitor.

14. The junction system as recited in claim 13, wherein the capacitance setting control includes a stepper motor that enables adjustment of the capacitance setting of the variable capacitor through transmission of electrical control signals to the stepper motor.

15. The junction system as recited in claim 1, further comprising:
a junction enclosure in which the reactive circuit is disposed; and
a cooling fan configured to circulate air through the junction enclosure.

16. A radiofrequency power transmission system for a plasma processing chamber, comprising:
a direct-drive radiofrequency signal generator;
a coil; and
a reactive circuit connected between an output of the direct-drive radiofrequency signal generator and the coil, the reactive circuit connected to receive a shaped-amplified square waveform signal from the output of the direct-drive radiofrequency signal generator, the reactive circuit configured to transform the shaped-amplified square waveform signal into a shaped-sinusoidal signal in route from the direct-drive radiofrequency signal generator to the coil.

17. The radiofrequency power transmission system as recited in claim 16, wherein the reactive circuit includes a variable capacitor having a capacitance set so that a peak amount of radiofrequency power is transmitted from the direct-drive radiofrequency signal generator through the reactive circuit to the coil.

18. The radiofrequency power transmission system as recited in claim 16, wherein the reactive circuit is configured to essentially cancel an inductive part of a load to which the direct-drive radiofrequency signal generator is connected by way of the coil so that the load is primarily a resistive load.

19. The radiofrequency power transmission system as recited in claim 16, wherein the direct-drive radiofrequency signal generator has a non-50 ohm output impedance.

20. The radiofrequency power transmission system as recited in claim 16, wherein the reactive circuit is configured to remove non-fundamental harmonic components of the shaped-amplified square waveform signal.

21. The radiofrequency power transmission system as recited in claim 16, wherein the shaped-amplified square waveform signal has a frequency of about 2 megaHertz and the reactive circuit provides a capacitance between the output of the direct-drive radiofrequency signal generator and the coil within a range extending from about 2500 picofarads to about 4500 picofarads, or
wherein the shaped-amplified square waveform signal has a frequency of about 13.56 megaHertz and the reactive circuit provides a capacitance between the output of the direct-drive radiofrequency signal generator and the coil within a range extending from about 5 picofarads to about 1000 picofarads.

22. A method for delivering radiofrequency power from a direct-drive radiofrequency power supply to a plasma processing chamber, comprising:
transmitting a shaped-amplified square waveform signal from an output of a direct-drive radiofrequency signal generator to a reactive circuit, the reactive circuit operating to transform the shaped-amplified square waveform signal into a shaped-sinusoidal signal;
transmitting the shaped-sinusoidal signal from an output of the reactive circuit to a coil of the plasma processing chamber, the shaped-sinusoidal signal conveying radiofrequency power to the coil; and
adjusting a capacitance setting within the reactive circuit so that a peak amount of radiofrequency power is transmitted from the direct-drive radiofrequency signal generator through the reactive circuit to the coil.

23. The method as recited in claim 22, wherein the direct-drive radiofrequency signal generator has a non-50 ohm output impedance.

24. The method as recited in claim 22, wherein the adjusting of the capacitance setting essentially cancels an inductive part of a load to which the direct-drive radiofrequency signal generator is connected by way of the coil so that the load is primarily a resistive load.

25. The method as recited in claim 22, wherein adjusting the capacitance setting removes non-fundamental harmonic components of the shaped-amplified square waveform signal.

26. The method as recited in claim 22, wherein the shaped-amplified square waveform signal has a frequency of about 2 MHz and the capacitance setting is adjusted within a range extending from about 2500 pF to about 4500 pF, or
wherein the shaped-amplified square waveform signal has a frequency of about 13.56 MHz and the capacitance setting is adjusted within a range extending from about 5 pF to about 1000 pF.
